(19) United States
(12) Patent Application Publication
(10) Pub. No.: US 2025/0248178 A1
(43) Pub. Date: Jul. 31, 2025

(54) PRODUCTION METHOD OF SEMICONDUCTOR NANOPARTICLE, and ELECTROLUMINESCENT DEVICE INCLUDING THE SEMICONDUCTOR NANOPARTICLE

(71) Applicant: Samsung Electronics Co., Ltd., Suwon-si (KR)

(72) Inventors: DAEUN YOON, Suwon-si (KR); Hyundong Ha, Suwon-si (KR); Ji Hyun MIN, Suwon-si (KR)

(21) Appl. No.: 19/036,676

(22) Filed: Jan. 24, 2025

(30) Foreign Application Priority Data
Jan. 29, 2024 (KR) 10-2024-0013461

(51) Int. Cl. H10H 20/823; B82Y 20/00; H10H 20/01; H10H 29/30

(52) U.S. Cl. CPC H10H 20/823; B82Y 20/00; H10H 20/012; H10H 29/30

(57) ABSTRACT

A method for producing a semiconductor nanoparticle, a semiconductor nanoparticle, an electroluminescent device including the semiconductor nanoparticle, and a display device. In an embodiment, the method of an embodiment includes preparing a first semiconductor nanocrystal including zinc, tellurium, and selenium, wherein the preparing of the first semiconductor nanocrystal includes heating a first solution including a first zinc precursor, a first selenium precursor and a tellurium precursor in a first organic solvent at a reaction temperature to form a heated solution; and adding an additive to the heated first solution to produce the first semiconductor nanocrystal, wherein the additive includes a second selenium precursor and the additive does not include tellurium, and the semiconductor nanoparticle is configured to emit blue light.

### CROSS-REFERENCE TO RELATED APPLICATION

This application claims priority to Korean Patent Application No. 10-2024-0013461 filed in the Korean Intellectual Property Office on Jan. 29, 2024, and all the benefits accruing therefrom under 35 U.S.C. § 119, the content of which in its entirety is herein incorporated by reference.

### BACKGROUND

### 1. Field

The present disclosure relates to a production method of a semiconductor nanoparticle, a semiconductor nanoparticle, and an electroluminescent device including the semiconductor nanoparticle.

### 2. Description of the Related Art

A semiconductor nanoparticle (e.g., a quantum dot) having a nanoscale size may exhibit a luminescent property. For example, a quantum dot including a semiconductor nanocrystal may exhibit a quantum confinement effect. Light emission of the semiconductor nanoparticle may be generated when electrons in an excited state transition from a conduction band to a valence band by, for example, light excitation or voltage application. The semiconductor nanoparticle may be configured to emit light in a desired wavelength region by controlling a size thereof, a composition thereof, or a combination thereof. The semiconductor nanoparticle may be used in various light emitting devices (e.g., electroluminescent devices) and display devices.

### SUMMARY

An embodiment relates to a method for producing blue light emitting semiconductor nanoparticles which can exhibit improved stability and luminescent properties.

An embodiment relates to the semiconductor nanoparticle produced by the method described above.

An embodiment relates to a light emitting device that emit light by themselves when voltage is applied to the aforementioned semiconductor nanoparticle (e.g., the quantum dot).

An embodiment relates to a display device (e.g., a quantum dot (QD)-light emitting diode (LED) display) comprising nanocrystal particles (e.g., quantum dots) as a light emitting material in red/green/blue pixels.

In an embodiment, a method for producing a semiconductor nanoparticle includes
preparing a first semiconductor nanocrystal including zinc, tellurium, and selenium; wherein the preparing of the first semiconductor nanocrystal includes:
heating a first solution including a first zinc precursor, a first selenium precursor and a tellurium precursor in a first organic solvent and optionally a first organic ligand at a reaction temperature (for example, for a first time period) to form a heated first solution; and
further adding an additive to the heated first solution (to produce the first semiconductor nanocrystal),
wherein the additive includes a second selenium precursor, and the additive does not include tellurium, and
the semiconductor nanoparticle is configured to emit blue light.

The additive may further include a zinc compound, hydrofluoric acid, or a combination thereof.

The method may further include heating a second zinc precursor and a chalcogen precursor in a second organic solvent in the presence of the first semiconductor nanocrystal and a second organic ligand to obtain the semiconductor nanoparticle (e.g., including the second semiconductor nanocrystal on the first semiconductor nanocrystal).

The second selenium precursor may be the same as or different from the first selenium precursor.

In the method, an amount of the second selenium precursor may be about 0.1 to about 10 moles per 1 mole of the first selenium precursor. The amount of the second selenium precursor may be greater than or equal to about 0.1 moles, greater than or equal to about 0.12 moles, greater than or equal to about 0.125 moles, greater than or equal to about 0.14 moles, greater than or equal to about 0.2 moles, greater than or equal to about 0.3 moles, greater than or equal to about 0.4 moles, or greater than or equal to about 0.5 moles per 1 mole of the first selenium precursor. The amount of the second selenium precursor may be less than or equal to about 8 moles, less than or equal to about 4 moles, or less than or equal to about 1 mole per 1 mole of the first selenium precursor.

The zinc compound may be the same as or different from the zinc precursor.

The zinc compound may include zinc carboxylate, zinc acetylacetonate, zinc halide, or a combination thereof.

The zinc compounds may be of two or more types.

The zinc compound may include zinc carboxylate and zinc halide.

The zinc halide may include zinc chloride.

The zinc precursor may include dialkylzinc.

The additive may be added one or more times or two or more times.

In the method, a total amount of the first selenium precursor and the second selenium precursor may be greater than or equal to about 10 moles, greater than or equal to about 15 moles, or greater than or equal to about 20 moles per 1 mole of the tellurium precursor.

In the method, the total amount of the first selenium precursor and the second selenium precursor may be less than or equal to about 60 moles, less than or equal to about 55 moles, less than or equal to about 50 moles, less than or equal to about 40 moles, less than or equal to about 28 moles, or less than or equal to about 21 moles per 1 mole of the tellurium precursor.

In the first semiconductor nanocrystal, a molar ratio of tellurium to selenium may be greater than or equal to about 0.0001:1 and less than or equal to about 0.08:1, less than or equal to about 0.07:1, less than or equal to about 0.053:1, or less than or equal to about 0.052:1.

In the first semiconductor nanocrystal, the molar ratio of tellurium to selenium may be less than or equal to about 0.033:1, or less than or equal to about 0.025:1.

In the first semiconductor nanocrystal, a molar ratio of zinc to a total of tellurium and selenium may be greater than or equal to about 1:1, or greater than or equal to about 1.1:1, or greater than or equal to about 1.2:1. In the first semiconductor nanocrystal, the molar ratio of zinc to the total of tellurium and selenium may be less than or equal to about 2.5:1, or less than or equal to about 1.3:1.

In the semiconductor nanoparticle, a molar ratio of tellurium to selenium may be greater than or equal to about 0.0005:1, or greater than or equal to about 0.001:1 and less than about 0.01:1, less than or equal to about 0.008:1, or less than or equal to about 0.007:1.

In the semiconductor nanoparticle, a molar ratio ((S+Se):Zn) of the total sum of sulfur and selenium to zinc may be greater than or equal to about 0.8:1 and less than about 0.86:1.

In the semiconductor nanoparticle, the molar ratio ((S+Se):Zn) of the total sum of sulfur and selenium to zinc may be in the range of about 0.87:1 to about 0.9:1.

The semiconductor nanoparticle may be configured to emit a first light when voltage is applied, and the first light or the electroluminescent peak wavelength of the semiconductor nanoparticle may be greater than or equal to about 455 nanometers (nm), greater than or equal to about 457 nm, greater than or equal to about 460 nm, or greater than or equal to about 461 nm and less than or equal to about 490 nm.

The semiconductor nanoparticle may have a ratio of an intensity at the trap emission wavelength (e.g., 500 nm or the peak emission wavelength+50 nm) to an intensity at the peak emission wavelength in the emission spectrum of less than or equal to about 0.25:1, less than or equal to about 0.2:1, less than or equal to about 0.15:1, or less than or equal to about 0.12:1.

In an embodiment, the semiconductor nanoparticle includes
zinc, tellurium, selenium, and sulfur;
the semiconductor nanoparticle does not include cadmium,
in the semiconductor nanoparticle, a molar ratio of tellurium to selenium is greater than or equal to about 0.0005:1 and less than or equal to about 0.008:1,
the semiconductor nanoparticle has a particle size or an average particle size of less than about 10.3 nm, or less than or equal to about 10.2 nm, and
the semiconductor nanoparticle has an absolute quantum efficiency of greater than or equal to about 90%.

The semiconductor nanoparticle may have a size or an average size (hereinafter, can be simply referred to as “size”) of less than or equal to about 10.1 nm, less than or equal to about 10 nm, less than or equal to about 9.9 nm, less than or equal to about 9.7 nm, less than or equal to about 9.6 nm, less than or equal to about 9.4 nm, less than or equal to about 9.2 nm, less than or equal to about 9 nm, less than or equal to about 8.8 nm, or less than or equal to about 8.4 nm.

The semiconductor nanoparticle may have an absolute quantum efficiency of greater than or equal to about 93%, greater than or equal to about 94%, greater than or equal to about 95%, or greater than or equal to about 96%.

In an embodiment, an electroluminescent device includes a first electrode and a second electrode spaced apart from each other, and a light emitting layer disposed between the first electrode and the second electrode, the light emitting layer including a semiconductor nanoparticle,
wherein the semiconductor nanoparticle contains zinc, tellurium, selenium, and sulfur,
the semiconductor nanoparticle does not include cadmium,
in the semiconductor nanoparticle, a molar ratio of tellurium to selenium is greater than or equal to about 0.0005:1 and less than or equal to about 0.008:1, and
the light emitting layer is configured to emit a first light by voltage application, and an electroluminescent peak wavelength of the first light or the semiconductor nanoparticle is greater than about 460 nm and less than or equal to about 490 nm.

The semiconductor nanoparticle may have a ratio of the intensity at the trap emission wavelength (e.g., 500 nm or the peak emission wavelength+50 nm) to the intensity at the peak emission wavelength in the emission spectrum of less than or equal to about 0.25:1, less than or equal to about 0.2:1, less than or equal to about 0.13:1, or less than or equal to about 0.12:1.

In the semiconductor nanoparticle, the molar ratio of tellurium to selenium may be less than or equal to about 0.007:1.

In the semiconductor nanoparticle, the molar ratio of tellurium to selenium may be less than or equal to about 0.003:1.

The peak emission wavelength of the first light may be greater than or equal to about 462 nm, greater than or equal to about 465 nm, or greater than or equal to about 467 nm.

The first light may have a full width at half maximum of less than or equal to about 45 nm.

In the semiconductor nanoparticle, a molar ratio ((S+Se):Zn) of the total sum of sulfur and selenium to zinc may be greater than or equal to about 0.8:1 and less than about 0.86:1.

In the semiconductor nanoparticle, the molar ratio ((S+Se):Zn) of the total sum of sulfur and selenium to zinc may be in the range of about 0.87:1 to about 0.9:1.

The electroluminescent device may have a maximum external quantum efficiency of greater than or equal to about 10%.

The electroluminescent device may have a maximum luminance of greater than or equal to about 75,000 cd/m².

The electroluminescent device may have a T90 of greater than or equal to about 10 hours when measured at 650 nit. The electroluminescent device may have a T50 of greater than or equal to about 100 hours when measured at 650 nit.

The electroluminescent device may have a T90 of greater than or equal to about 20 hours when measured at 146 nit. The electroluminescent device may have a T50 of greater than or equal to about 150 hours when measured at 146 nit.

In an embodiment, a display device or an electronic device may include the electroluminescent device or the semiconductor nanoparticle.

The display device or the electronic device may include a virtual reality device, an augmented reality device, a portable terminal, a monitor, a laptop, a television, an electronic board, a camera, or an electrical component.

In an embodiment, a semiconductor nanoparticle includes a core including a first semiconductor nanocrystal comprising zinc, tellurium, and selenium; and an additional semiconductor nanocrystal (e.g., a third semiconductor nanocrystal) on the core, the additional semiconductor nanocrystal including zinc and sulfur, wherein the core has a decreasing tellurium concentration gradient in a direction from a center of the core to the additional semiconductor nanocrystal.

According to the production method of an embodiment, surface oxidation of the first semiconductor nanocrystal can be effectively suppressed, and the semiconductor nanoparticle produced thereby can emit blue light of a relatively long wavelength when applied to, for example, an electroluminescent device. The semiconductor nanoparticle of the embodiment can exhibit a relatively reduced level of trap emission as confirmed in the emission spectrum, and an electroluminescent device including the same can exhibit improved efficiency and life-span characteristics.

### BRIEF DESCRIPTION OF THE DRAWINGS

The above and other advantages and features of this disclosure will become more apparent by describing in further detail exemplary embodiments thereof with reference to the accompanying drawings, in which:

FIG. 1 is a schematic cross-sectional view of an embodiment of a QD-LED device;

FIG. 2 is a schematic cross-sectional view of an embodiment of a QD-LED device;

FIG. 3 is a schematic cross-sectional view of an embodiment of a QD-LED device;

FIG. 4 is a schematic cross-sectional view of an embodiment of a QD-LED device;

FIG. 5A, FIG. 5B, and FIG. 5C are views showing the schematic structures of the first semiconductor nanocrystal and the semiconductor nanoparticle thus formed during the synthesis processes wherein distributions of the tellurium in the first semiconductor nanocrystal and the semiconductor nanoparticle during the formation are illustrated, respectively;

FIG. 6 is a schematic cross-sectional view of a light emitting device (red-green-blue (RGB) pixel) according to an embodiment;

FIG. 7 is a schematic front view of a display panel according to an embodiment;

FIG. 8 is a schematic cross-sectional view of the display panel of FIG. 7 taken along line IV-IV;

FIG. 9 is a graph of arbitrary units (A.U.) versus wavelength (nm) showing the results of ultraviolet (UV)-visible (Vis) absorption spectroscopy of a sample collected from the reaction solution after the first reaction in Preparation Example 1;

FIG. 10 is a graph of arbitrary units versus wavelength showing the photoluminescence spectrum of the semiconductor nanoparticle produced in Preparation Example 1;

FIG. 11 is a transmission electron microscopy (TEM) image of the semiconductor nanoparticle produced in Preparation Example 1; and

FIG. 12 is a TEM image of the semiconductor nanoparticle produced in Comparative Preparation Example 1.

### DETAILED DESCRIPTION

Hereinafter, with reference to the accompanying drawings, various embodiments of the present disclosure will be described in detail so that those of ordinary skill in the art can easily carry out the present disclosure. The present disclosure may be embodied in many different forms and is not limited to the embodiments described herein.

In order to clearly explain the present disclosure, parts irrelevant to the description are omitted, and the same reference numerals are assigned to the same or similar elements throughout the specification.

The size and thickness of each constituent element as shown in the drawings are randomly indicated for better understanding and ease of description, and this disclosure is not necessarily limited to as shown. In the drawings, the thickness of layers, films, panels, regions, etc., are exaggerated for clarity. And in the drawings, for convenience of description, the thickness of some layers and regions are exaggerated.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. Also, to be disposed “on” the reference portion means to be disposed above or below the reference portion, and does not necessarily mean “above” in an opposite direction of gravity.

Relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

It will be understood that, although the terms “first,” “second,” “third,” etc. may be used herein to describe various elements, components, regions, layers, and/or sections, these elements, components, regions, layers and/or sections should not be limited by these terms. These terms are only used to distinguish one element, component, region, layer, or section from another element, component, region, layer, or section. Thus, “a first element,” “component,” “region,” “layer,” or “section” discussed below could be termed a second element, component, region, layer, or section without departing from the teachings herein.

In addition, unless explicitly described to the contrary, the word “comprise” and variations such as “comprises” or “comprising” will be understood to imply the inclusion of stated elements but not the exclusion of any other elements.

In the specification, “cross-section” may mean a cross-section viewed from the side that is cut generally vertically (e.g., substantially vertically to the bottom surface) through the target portion.

Further, the singular includes the plural unless mentioned otherwise.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. Thus, reference to “an” element in a claim followed by reference to “the” element is inclusive of one element and a plurality of the elements. “At least one” is not to be construed as limiting “a” or “an.” “Or” means “and/or.” As used herein, the term “and/or” includes any and all combinations of one or more of the associated listed items.

In the drawings, the thickness of layers, films, panels, regions, etc., are exaggerated for clarity. Like reference numerals designate like elements throughout the specification.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, values of a work function or (highest occupied molecular orbital (HOMO) or lowest unoccupied molecular orbital (LUMO)) energy levels are expressed as an absolute value from a vacuum level. In addition, a deep, a high, or large work function or energy level means that the absolute value is large when the vacuum level is set to “0 eV,” and a shallow, low, or small work function or energy level means that the absolute value is small when the vacuum level is set to “0 eV.”

In an embodiment, the work function may refer to a minimum energy required to remove an electron from a solid metal (e.g., the metal surface) to a vacuum (e.g., the portion just outside the solid surface).

The average may be mean or median. In an embodiment, the average is the mean.

As used herein, the term “peak emission wavelength” is the wavelength at which a given emission spectrum of the light reaches its maximum.

The first absorption peak refers to the main excitonic peak that first appears from the lowest wavelength region in the UV-Vis absorption spectrum, and the first absorption peak wavelength refers to the wavelength at which the first absorption peak exhibits maximum intensity.

In this specification, “Group” means a group of the periodic table of elements.

“Group III” may include Group IIIA and Group IIIB, examples of Group III metals include, but are not limited to, Al, In, Ga, and TI.

“Group V” includes Group VA and includes, but is not limited to, nitrogen, phosphorus, arsenic, antimony, and bismuth.

As used herein, when a definition is not otherwise provided, “substituted” refers to replacement of a, e.g., at least one, hydrogen of a compound or the corresponding moiety by a substituent that may be a C1 to C30 alkyl group, a C2 to C30 alkenyl group, a C2 to C30 alkynyl group, a C6 to C30 aryl group, a C7 to C30 alkylaryl group, a C1 to C30 alkoxy group, a C1 to C30 heteroalkyl group, a C3 to C30 heteroaryl group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a cyano group (—CN), an amino group (—NRR′ wherein R and R′ are each independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O)OR, wherein R is a C1 to C6 alkyl group or a C6 to C12 aryl group), a carboxyl group (—COOH) or a salt thereof (—C(═O)OM, wherein M is an organic or inorganic cation), a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), or a combination thereof.

As used herein, when a definition is not otherwise provided, “hydrocarbon group” refers to a group containing carbon and hydrogen (e.g., an aliphatic group such as alkyl, alkenyl, or alkynyl group, or an aromatic group such as aryl group). The hydrocarbon group may be a group having a monovalence or greater valence formed by removal of one or more hydrogen atoms from alkane, alkene, alkyne, or arene. In the hydrocarbon group, a, e.g., at least one, methylene may be replaced by an oxide moiety, a carbonyl moiety, an ester moiety, —NH—, or a combination thereof. Unless otherwise stated to the contrary, the hydrocarbon (alkyl, alkenyl, alkynyl, or aryl) group may have 1 to 60, 2 to 32, 3 to 24, or 4 to 12 carbon atoms.

As used herein, when a definition is not otherwise provided, “alkyl” refers to a linear or branched saturated monovalent hydrocarbon group (methyl, ethyl hexyl, etc.).

As used herein, when a definition is not otherwise provided, “alkenyl” refers to a linear or branched monovalent hydrocarbon group having one or more carbon-carbon double bond.

As used herein, when a definition is not otherwise provided, “alkynyl” refers to a linear or branched monovalent hydrocarbon group having one or more carbon-carbon triple bond.

As used herein, when a definition is not otherwise provided, “aryl” refers to a group formed by removal of a, e.g., at least one, hydrogen from an aromatic hydrocarbon (e.g., a phenyl or naphthyl group).

As used herein, when a definition is not otherwise provided, “hetero” refers to one including 1 to 3 heteroatoms of N, O, S, Si, P, or a combination thereof.

As used herein, when a definition is not otherwise provided, “alkoxy” means alkyl group linked via an oxygen (i.e., alkyl-O—), such as a methoxy, ethoxy, or sec-butyloxy group.

As used herein, when a definition is not otherwise provided, an “amine group” may be —NRR′, wherein R and R′ are each independently hydrogen, a C1 to C12 alkyl group, a C7 to C20 alkylaryl group, a C7 to C20 arylalkyl group, or a C6 to C18 aryl group.

A description of not containing cadmium (or other toxic heavy metals) may refer to a concentration of cadmium (or a corresponding heavy metal) of less than or equal to about 100 parts per million by weight (ppmw), less than or equal to about 50 ppmw, less than or equal to about 10 ppmw, almost zero, or zero (e.g., undetectable by current methods). In an embodiment, substantially no cadmium, its salt, (or other heavy metal) is present, or, if present, in an amount or impurity level below the detection limit of a given detection means. As used herein, “substantially” or “approximately” or “about” means not only the stated value, but also the mean within an acceptable range of deviations, considering the errors associated with the corresponding measurement and the measurement of the measured value. For example, “substantially” or “approximately” or “about” can mean within ±10%, 5%, 3%, or 1% or within standard deviation of the stated value.

A nanoparticle refers to a structure having at least one region or characteristic dimension with a nanoscale dimension. In an embodiment, the dimension of the nanoparticle may be less than or equal to about 300 nm, less than or equal to about 250 nm, less than or equal to about 150 nm, less than or equal to about 100 nm, less than or equal to about 50 nm, or less than or equal to about 30 nm. Such a nanoparticle may have any suitable shape.

The nanoparticle may have any suitable shape, such as nanowires, nanorods, nanotubes, multi-pod type shapes having two or more pods, nanodots (or quantum dots), etc. and are not particularly limited. The nanoparticles may be, for example, substantially crystalline, substantially monocrystalline, polycrystalline, amorphous, or a combination thereof.

For example, semiconductor nanoparticles such as quantum dots may exhibit quantum confinement or exciton confinement. In the present specification, the term “nanoparticles or quantum dots” are not limited in shapes thereof unless specifically defined. Semiconductor nanoparticles, such as quantum dots, may have a size smaller than a diameter of Bohr excitation in the bulk crystal of the same material, and may exhibit a quantum confinement effect. Quantum dots may emit light corresponding to bandgap energies thereof by controlling the size of the nanocrystals as the emission center.

T50 refers to time taken for luminance of a given device to decrease to 50% based on 100% of the initial luminance when the device is driven at predetermined luminance (e.g., 650 nit or 146 nit).

T90 refers to time taken for luminance of a given device to decrease to 90% based on 100% of the initial luminance when the device is driven at predetermined luminance (e.g., 650 nit or 146 nit).

Herein, external quantum efficiency refers to a ratio of the number of photons emitted from a light emitting diode (LED) to the number of electrons passing through the device. External quantum efficiency (EQE) may be a criteria of how efficiently the light emitting diode converts the electrons into the photons and allows them to escape. In an embodiment, EQE may be determined based on the following equation:

$$EQE = ( Injection efficiency ) \times ( Solid state quantum yield ) \times ( Extraction efficiency )$$

Injection efficiency=proportion of electrons passing through the device that are injected into the active region;
Solid state quantum yield=proportion of all electron-hole recombinations in the active region that are radiative and thus, produce photons; and
Extraction efficiency=proportion of photons generated in the active region that escape from the device.

The maximum external quantum efficiency refers to the maximum value of the external quantum efficiency.

The maximum luminance refers to a maximum value of luminance that the device can achieve.

Quantum efficiency is a term used interchangeably with quantum yield. Quantum efficiency (or quantum yield) may be measured either in solution or in the solid state (in a composite). In an embodiment, quantum efficiency (or quantum yield) is the ratio of photons emitted to photons absorbed by the nanostructure or population thereof. In an embodiment, quantum efficiency may be measured by any suitable method. For example, for fluorescence quantum yield or efficiency, there may be two methods: an absolute method and a relative method.

In the absolute method, quantum efficiency is obtained by detecting the fluorescence of all samples through an integrating sphere. In the relative method, the quantum efficiency of the unknown sample is calculated by comparing the fluorescence intensity of a standard dye (standard sample) with the fluorescence intensity of the unknown sample. Coumarin 153, Coumarin 545, Rhodamine 101 inner salt, Anthracene and Rhodamine 6G may be used as standard dyes according to photoluminescent (PL) wavelengths thereof, but the present disclosure is not limited thereto.

Unless otherwise stated, numerical ranges stated herein are inclusive. Unless mentioned to the contrary, a numerical range recited herein includes any real number within the endpoints of the stated range and includes the endpoints thereof. In this specification, a numerical endpoint or an upper or lower limit value (e.g., recited either as a “greater than or equal to value” “at least value” or a “less than or equal to value” or recited with “from” or “to”) may be used to form a numerical range of a given feature. In other words, the upper and lower endpoints set forth for various numerical values may be independently combined to provide a range.

A bandgap energy of the semiconductor nanoparticle may be changed according to a size, a structure, and a composition of nanocrystal. For example, as the size of the quantum dot increases, the quantum dot may have a narrow bandgap energy and an increased emission wavelength. The semiconductor nanocrystal has drawn attention as light emitting materials in various fields of a display device, an energy device, or a bio light emitting device.

A semiconductor nanoparticle having electroluminescent properties at a practically applicable level may include harmful heavy metals such as cadmium (Cd), lead, mercury, or a combination thereof. It is desirable to provide a semiconductor nanoparticle that emits light of a desired wavelength (e.g., blue light of relatively low energy) while being substantially free of the harmful heavy metals. In addition, from an environmental point of view, it is desirable to provide a light emitting device or a display device (e.g., emitting blue light) having a light emitting layer based on semiconductor nanoparticles that does not include cadmium, a harmful heavy metal.

A semiconductor nanoparticle according to an embodiment are environmentally friendly, can emit blue light of a desired wavelength with improved luminous efficiency, and can exhibit improved stability in the external environment. An electroluminescent device according to an embodiment is a self-emissive light emitting device that includes the semiconductor nanoparticle and is configured to emit desired light by voltage application with or without a separate light source. The light emitting device and display device of an embodiment are desirable from an environmental point of view.

In an embodiment, a semiconductor nanoparticle includes zinc, tellurium, selenium, and sulfur, the semiconductor nanoparticle does not include cadmium, a molar ratio of tellurium to selenium in the semiconductor nanoparticle is greater than or equal to about 0.0005:1 and less than or equal to about 0.008:1, and the semiconductor nanoparticle is configured to emit light having a peak emission wavelength of greater than about 460 nm, for example, greater than or equal to about 461 nm and less than or equal to about 490 nm, when voltage is applied. In the semiconductor nanoparticle, a molar ratio of tellurium to selenium may be less than or equal to about 0.007:1, or less than or equal to about 0.003:1. An embodiment relates to an electronic device (e.g., an electroluminescent device) including the semiconductor nanoparticle (e.g., in a light emitting layer).

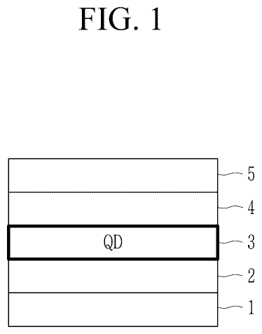

In an embodiment, the electroluminescent device includes a first electrode 1 and a second electrode 5 which are spaced apart (e.g., facing each other); and a light emitting layer 3 disposed between the first electrode and the second electrode and including the semiconductor nanoparticle and not including cadmium (see FIG. 1). The first electrode may include an anode, and the second electrode may include a cathode. Alternatively, the first electrode may include a cathode and the second electrode may include an anode. The electroluminescent device may further include a hole auxiliary layer 2 between the light emitting layer and the first electrode. The electroluminescent device may further include an electron auxiliary layer 4 between the light emitting layer and the second electrode.

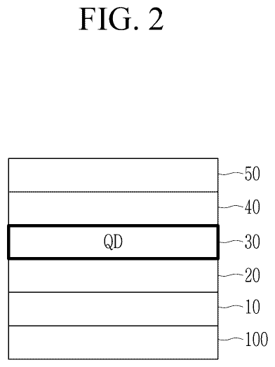

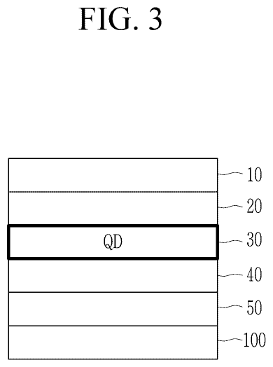

In the electroluminescent device, he first electrode 10 or the second electrode 20 may be disposed on a (transparent) substrate 100. The transparent substrate may be a light extraction surface. (Refer to: FIG. 2 and FIG. 3)

Referring to FIGS. 2 and 3, the light emitting layer 30 may be disposed between the first electrode (e.g., anode) 10 and second electrode (e.g., cathode) 50. The second electrode or cathode 50 may include an electron injection conductor. The first electrode or anode 10 may include a hole injection conductor. The work functions of the electron/hole injection conductors included in the second electrode and the first electrode may be appropriately adjusted and are not particularly limited. For example, the second electrode may have a small work function and the first electrode may have a relatively large work function, or vice versa.

The electron/hole injection conductors may include a metal-based material (e.g., a metal, a metal compound, an alloy, or a combination thereof) (aluminum, magnesium, tungsten, nickel, cobalt, platinum, palladium, calcium, LiF, or the like), a metal oxide such as gallium indium oxide or indium tin oxide (ITO), or a conductive polymer (e.g., having a relatively high work function) such as polyethylene dioxythiophene, but are not limited thereto.

The first electrode, the second electrode, or a combination thereof may be a light transmitting electrode or a transparent electrode. In an embodiment, both the first electrode and the second electrode may be a light transmitting electrode. The electrode(s) may be patterned. The first electrode, the second electrode, or a combination thereof may be disposed on a (e.g., insulating) substrate 100. The substrate 100 may be optically transparent (e.g., may have a light transmittance of greater than or equal to about 50%, greater than or equal to about 60%, greater than or equal to about 70%, greater than or equal to about 80%, greater than or equal to about 85%, or greater than or equal to about 90% and for example, less than or equal to about 99%, or less than or equal to about 95%). The substrate may further include a region for a blue pixel, a region for a red pixel, a region for a green pixel, or a combination thereof. A thin film transistor may be disposed in each region of the substrate, and one of a source electrode and a drain electrode of the thin film transistor may be electrically connected to the first electrode or the second electrode.

The light transmitting electrode may be disposed on a (e.g., insulating) transparent substrate. The substrate may be rigid or flexible. The substrate may be plastic, glass, or a metal.

The light transmitting electrode can have a light transmittance of greater than or equal to about 50%, greater than or equal to about 60%, greater than or equal to about 70%, greater than or equal to about 80%, or greater than or equal to about 90%, for example, in the range of about 80% to about 100%, about 85% to about 95%, or a combination thereof.

The light transmitting electrode may include, for example, a transparent conductor such as indium tin oxide (ITO) or indium zinc oxide (IZO), gallium indium tin oxide, zinc indium tin oxide, titanium nitride, polyaniline, LiF/Mg:Ag, or the like, or a metal thin film of a single layer or a plurality of layers, but is not limited thereto. The first electrode, the second electrode, or a combination thereof may include silver, aluminum (Al), a lithium aluminum (Li:Al) alloy, a magnesium-silver alloy (Mg:Ag), lithium fluoride-aluminum (LiF:Al), or the like. In an alloy electrode, a ratio between each material can be appropriately controlled, for example, in the range of about 1:0.1 to about 1:10, about 1:0.2 to about 1:5, about 1:0.3 to about 1:3, or a combination thereof.

In an embodiment, the first electrode or the second electrode may be a multilayer electrode. In an embodiment, the first electrode (or anode) may be a multilayer electrode including two or more layers, three or more layers and ten or fewer layers, or five or fewer layers of electrode material. In an embodiment, the second electrode (or cathode) may be a multilayer electrode including two or more layers, three or more layers and ten or fewer layers, or five or fewer layers of electrode material.

The multilayer electrode may include, for example, a light transmitting conductive material such as indium tin oxide, an opaque conductive material (or reflective electrode material) such as aluminum, or a combination thereof. In an embodiment, the electrode (e.g., an anode or a cathode) may have a structure in which an opaque conductive material (or a reflective electrode material layer) is disposed between transparent conductive materials (e.g., layers of transparent conductive materials). In an embodiment, the electrode (anode or cathode) may have a structure in which a light transmitting conductive material (e.g., a light transmitting conductive material layer) is disposed between opaque conductive materials (or reflective electrode materials).

When a voltage is applied between the first electrode and the second electrode, the light emitting layer can emit light up and down by the electric field, and the light traveling to the reflective electrode can be reflected and emitted in the opposite direction.

In an embodiment, light may be emitted toward the cathode. In an embodiment, light may be emitted toward the anode.

The thickness of the electrode (the first electrode, the second electrode, or a combination thereof) is not particularly limited and may be appropriately selected in consideration of device efficiency. For example, the thickness of the electrode may be greater than or equal to about 5 nm, for example, greater than or equal to about 10 nm, greater than or equal to about 20 nm, greater than or equal to about 30 nm, greater than or equal to about 40 nm, or greater than or equal to about 50 nm. For example, the thickness of the electrode may be less than or equal to about 100 micrometers (μm), for example, less than or equal to about 90 μm, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 10 μm, less than or equal to about 1 μm, less than or equal to about 900 nm, less than or equal to about 500 nm, less than or equal to about 100 nm, less than or equal to about 90 nm, less than or equal to about 80 nm, less than or equal to about 70 nm, or less than or equal to about 60 nm.

The method of forming the electrode is not particularly limited and may be appropriately selected depending on the material. In an embodiment, the electrode may be formed by, but is not limited to, deposition, coating, or a combination thereof.

A light emitting layer 3 or 30 is disposed between the first electrode 1 and the second electrode 5 (e.g., the anode 10 and the cathode 50). The light emitting layer includes semiconductor nanoparticle(s) (e.g., blue light emitting nanoparticle, red light emitting nanoparticle, or green light emitting nanoparticle). The light emitting layer may include one or more (e.g., 2 or more or 3 or more and 10 or less) monolayers of a plurality of nanoparticles.

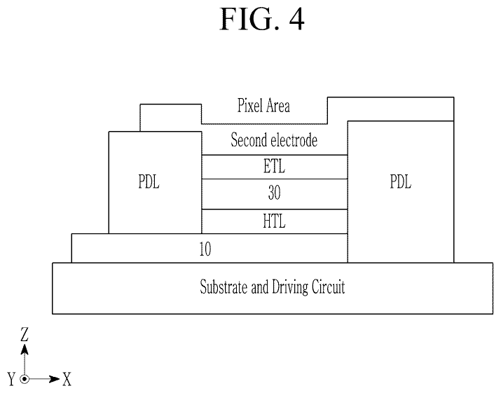

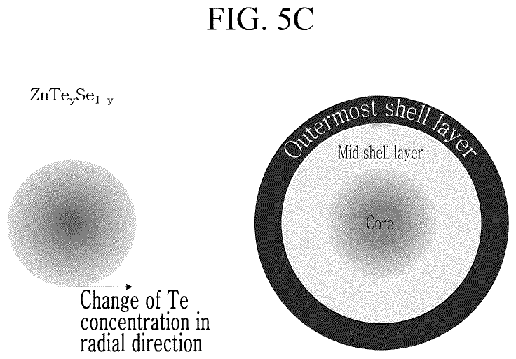

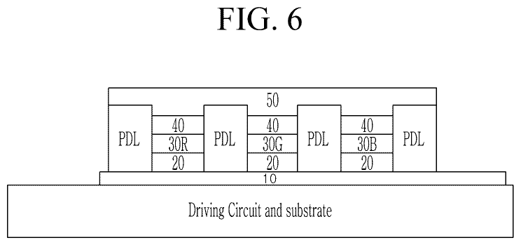

The light emitting layer may be patterned. In an embodiment, the patterned light emitting layer may include a blue light emitting layer (e.g., disposed within a blue pixel in a display device to be described later), a red light emitting layer (e.g., disposed within a red pixel in a display device to be described later), a green light emitting layer (e.g., disposed within a green pixel in a display device to be described later)), or a combination thereof. Each of the light emitting layers may be (e.g., optically) separated from an adjacent light emitting layer by a partition wall. In an embodiment, a partition wall or bank such as a black matrix or a pixel defining layer (PDL) may be disposed between the red emitting layer(s), the green emitting layer(s), and the blue emitting layer(s) (refer to FIGS. 4 and 6). In an embodiment, the red emitting layer, the green emitting layer, and the blue emitting layer may each be optically substantially isolated.

In an embodiment, the light emitting layer may not include cadmium. In an embodiment, the light emitting layer or the semiconductor nanoparticle may not contain mercury, lead, or a combination thereof.

The semiconductor nanoparticle included in the light emitting layer 3 or 30 may include zinc, tellurium, and selenium. The semiconductor nanoparticle may further include sulfur. An embodiment relates to the semiconductor nanoparticle or a population thereof.

The semiconductor nanoparticle may include a first semiconductor nanocrystal (including a first zinc chalcogenide) including zinc, tellurium, and selenium, or a core including the same. The semiconductor nanoparticle may include a semiconductor nanocrystal (including zinc chalcogenide) including zinc, selenium, sulfur, or a combination thereof, or a shell including the same. In an embodiment, the semiconductor nanoparticle may not include a Group III-V compound including indium and phosphorus. In an embodiment, the semiconductor nanoparticle may not include indium phosphide, indium gallium phosphide, indium zinc phosphide, or a combination thereof. The semiconductor nanoparticle may exhibit an emission peak wavelength, for example, a photoluminescent peak wavelength or an electroluminescent peak wavelength, in a range of greater than or equal to about 420 nm, greater than or equal to about 430 nm, greater than or equal to about 440 nm, greater than or equal to about 445 nm, greater than or equal to about 448 nm, greater than or equal to about 450 nm, greater than or equal to about 452 nm, greater than or equal to about 453 nm, greater than or equal to about 454 nm, greater than or equal to about 455 nm, greater than or equal to about 457 nm, greater than or equal to about 459 nm, or greater than or equal to about 461 nm and less than or equal to about 480 nm, less than or equal to about 475 nm, less than or equal to about 470 nm, less than or equal to about 465 nm, or less than or equal to about 462 nm. The semiconductor nanoparticle may be configured to exhibit an absolute quantum yield of greater than or equal to about 80%, greater than or equal to about 90%, greater than or equal to about 92%, greater than or equal to about 93%, greater than or equal to about 94%, greater than or equal to about 95%, or greater than or equal to about 96% in photoluminescence spectroscopy. The semiconductor nanoparticle may be configured to exhibit a full width at half maximum (FWHM) of less than or equal to about 55 nm, less than or equal to about 52 nm, less than or equal to about 50 nm, less than or equal to about 49 nm, less than or equal to about 48 nm, less than or equal to about 45 nm, or less than or equal to about 43 nm.

A zinc, selenium, and tellurium-based, e.g., containing, cadmium-free semiconductor nanocrystal or semiconductor nanoparticle including the same is capable of emitting blue light. The composition of the semiconductor nanoparticle may be varied to provide for emission of blue light of a desired wavelength. For example, the semiconductor nanoparticle may emit blue light of relatively long wavelengths. The present inventors have found that when a zinc, selenium and tellurium-based cadmium-free semiconductor nanoparticle emit blue light with a relatively long wavelength, a significant degree of trap emission can appear in the trap emission wavelength region (e.g., greater than 500 nm). Without wishing to be bound by any theory, it is believed that in the semiconductor nanoparticle emitting relatively long-wavelength blue light, tellurium, which is vulnerable to oxidation, may exist on the surface of a ZnTeSe semiconductor nanocrystal (or a core), leading to core surface oxidation and an increase in core-shell interface defects. The semiconductor nanoparticle may cause unwanted decreases in quantum efficiency and stability in electroluminescent devices.

Surprisingly, the present inventors have found that the semiconductor nanoparticle of an embodiment can be synthesized by the method described herein and exhibit the characteristics described herein, and can exhibit enhanced luminous efficiency and enhanced stability at a desired emission peak wavelength. Although not intended to be bound by a specific theory, it is believed that in the semiconductor nanoparticle obtained by the production method of the exemplary embodiment, the internal concentration of tellurium within the first semiconductor nanocrystal may be increased, thereby reducing surface oxidation of the core and the occurrence of core/shell interface defects due to tellurium exposure. In addition, the semiconductor nanoparticle of an embodiment can contribute to improving device efficiency and extending the life-span when applied to an electroluminescent device that includes the semiconductor nanoparticle as a light emitting material in a light emitting layer.

In an embodiment, the semiconductor nanoparticle may have a core-shell structure. The core-shell structure may include a core including a first semiconductor nanocrystal and a shell disposed on the core and including a semiconductor nanocrystal.

In an embodiment, the first semiconductor nanocrystal or the core may include a first zinc chalcogenide including zinc, selenium, and tellurium. The size or average size (hereinafter, abbreviated as “size”) of the core may be greater than or equal to about 2 nm, greater than or equal to about 2.5 nm, greater than or equal to about 3 nm, greater than or equal to about 3.5 nm, greater than or equal to about 4 nm, or greater than or equal to about 4.5 nm. The size of the core may be less than or equal to about 6 nm, for example, less than or equal to about 5 nm. The size of the core may be about 2 nm to about 6 nm, or about 2.5 nm to about 5 nm. The first semiconductor nanocrystal may include ZnTeₓSe₁₋ₓ (wherein, x is greater than 0, greater than or equal to about 0.0001, greater than or equal to about 0.001, greater than or equal to about 0.003, greater than or equal to about 0.005, greater than or equal to about 0.007, greater than or equal to about 0.009, greater than or equal to about 0.01, greater than or equal to about 0.03, greater than or equal to about 0.05, greater than or equal to about 0.09 and less than or equal to about 0.1, less than or equal to about 0.05, less than or equal to about 0.04, less than or equal to about 0.03, less than or equal to about 0.02, less than or equal to about 0.01, or less than or equal to about 0.08). The core may or may not further include sulfur.

In an embodiment, in the first semiconductor nanocrystal or the core, the distribution of Te element may be concentrated at the center of the particle, and such a structure may be obtained, for example, by the synthesis method described herein. In an embodiment, a difference in reactivity between tellurium precursor and selenium precursor can be utilized. In an embodiment, the method of adding multiple precursors (e.g., selenium precursors) to the reaction system in a split (i.e., a portion wise) manner or separate addition of additives can contribute to providing a core having a gradient in the concentration of the tellurium element. In the first semiconductor nanocrystal or core obtained in this way, surface oxidation due to exposure of tellurium can be suppressed, and the occurrence frequency of core-shell interface defects in the subsequent shell formation reaction can be reduced. Additionally, the trap emission of the semiconductor nanoparticle of an embodiment may be reduced compared to the particle produced according to conventional techniques. A semiconductor nanoparticle of an embodiment, when included in an electroluminescent device, can contribute to improving the efficiency and extending the life-span of the device.

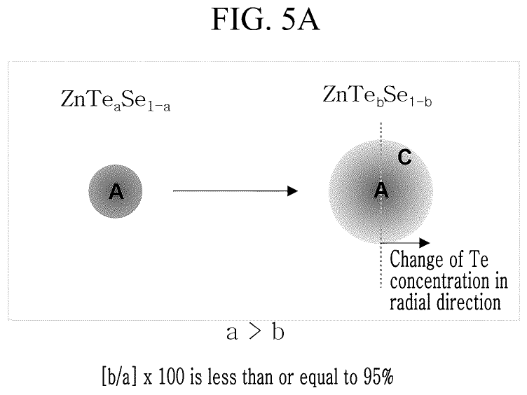

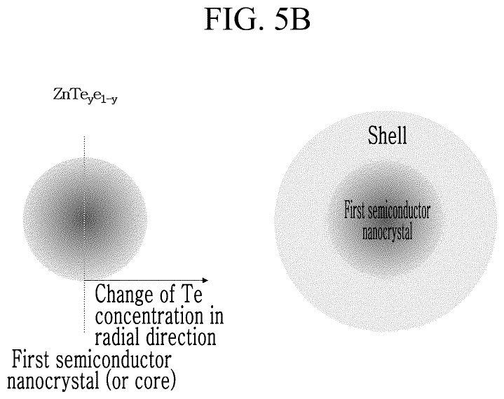

The first semiconductor nanocrystal or core of an embodiment has a concentration gradient of tellurium, for example, it can exhibit a difference in concentration of tellurium between the central portion A and the adjacent surface portion C. FIG. 5A schematically illustrates the distribution of a tellurium atom within the core of a semiconductor nanoparticle, in an embodiment. Referring to FIG. 5A, when the composition at the core central portion A is ZnTeₐSe₁₋ₐ (wherein a is a number representing the relative molar ratio between tellurium and selenium, greater than 0 and less than 1) and the composition of the first semiconductor nanocrystal is ZnTe_{b}Se_{1-b} (wherein b is a number representing the relative molar ratio between tellurium and selenium, greater than 0 and less than 1), a may be greater than b. For example, the relative molar ratio between tellurium and selenium can be represented by the following equation, respectively:

$$Mole number of \text{} Tellurium / ( Mole number of Tellurium + Mole number of Selenium )$$

In an embodiment, the first semiconductor nanocrystal may have a tellurium distribution index (%) represented by (b/a)×100 of less than or equal to about 95%, less than or equal to about 90%, less than or equal to about 85%, less than or equal to about 80%, less than or equal to about 75%, less than or equal to about 70%, less than or equal to about 65%, less than or equal to about 60%, less than or equal to about 55%, less than or equal to about 50%, less than or equal to about 45%, or less than or equal to about 40%.

In the semiconductor nanoparticle of an embodiment, the first semiconductor nanocrystal may have the Te element concentrated in the central portion. In an embodiment, the tellurium distribution index can represent the distribution uniformity of tellurium, and a smaller distribution index value can indicate a greater concentration of tellurium at the central portion. In the first semiconductor nanocrystal, the tellurium distribution index (percentage) may be in a range of about 1% to about 95%, about 5% to about 87%, about 9% to about 83%, about 11% to about 79%, about 14% to about 77%, about 18% to about 73%, about 21% to about 63%, about 29% to about 45%, about 32% to about 41%, or a combination of the upper and lower limits described herein.

In the first semiconductor nanocrystal of an embodiment, the central portion A may have a diameter of greater than or equal to about 1.5 nm, greater than or equal to about 2 nm, or greater than or equal to about 2.5 nm and less than or equal to about 4 nm, or less than or equal to about 3.5 nm.

In the first semiconductor nanocrystal, a molar ratio of tellurium to selenium may be greater than or equal to about 0.0001:1, greater than or equal to about 0.0005:1, greater than or equal to about 0.001:1, greater than or equal to about 0.005:1, greater than or equal to about 0.01:1, greater than or equal to about 0.015:1, greater than or equal to about 0.02:1, greater than or equal to about 0.022:1, greater than or equal to about 0.025:1, greater than or equal to about 0.03:1, greater than or equal to about 0.031:1, greater than or equal to about 0.035:1, greater than or equal to about 0.04:1, greater than or equal to about 0.045:1, greater than or equal to about 0.05:1, greater than or equal to about 0.051:1, greater than or equal to about 0.065:1, greater than or equal to about 0.07:1, greater than or equal to about 0.074:1, or greater than or equal to about 0.078:1. In the first semiconductor nanocrystal, the molar ratio of tellurium to selenium may be less than or equal to about 0.08:1, less than or equal to about 0.079:1, less than or equal to about 0.077:1, less than or equal to about 0.073:1, less than or equal to about 0.071:1, less than or equal to about 0.069:1, less than or equal to about 0.06:1, less than or equal to about 0.055:1, less than or equal to about 0.053:1, less than or equal to about 0.052:1, less than or equal to about 0.051:1, less than or equal to about 0.05:1, less than or equal to about 0.048:1, less than or equal to about 0.047:1, less than or equal to about 0.046:1, less than or equal to about 0.045:1, less than or equal to about 0.044:1, less than or equal to about 0.043:1, less than or equal to about 0.042:1, less than or equal to about 0.041:1, less than or equal to about 0.040:1, less than or equal to about 0.039:1, less than or equal to about 0.038:1, less than or equal to about 0.037:1, less than or equal to about 0.036:1, less than or equal to about 0.035:1, less than or equal to about 0.034:1, less than or equal to about 0.033:1, less than or equal to about 0.032:1, less than or equal to about 0.031:1, less than or equal to about 0.030:1, less than or equal to about 0.029:1, less than or equal to about 0.028:1, less than or equal to about 0.027:1, less than or equal to about 0.026:1, less than or equal to about 0.025:1, less than or equal to about 0.024:1, less than or equal to about 0.023:1, less than or equal to about 0.022:1, less than or equal to about 0.021:1, or less than or equal to about 0.02:1.

In the first semiconductor nanocrystal, the molar ratio of zinc to the total of tellurium and selenium may be greater than or equal to about 1:1, greater than or equal to about 1.1:1, greater than or equal to about 1.15:1, greater than or equal to about 1.16:1, greater than or equal to about 1.2:1, greater than or equal to about 1.22:1, greater than or equal to about 1.23:1, greater than or equal to about 1.25:1, or greater than or equal to about 1.28:1. In the first semiconductor nanocrystal, the molar ratio of zinc to the total sum of tellurium and selenium may be less than or equal to about 2.5:1, less than or equal to about 2.1:1, less than or equal to about 2:1, less than or equal to about 1.8:1, less than or equal to about 1.7:1, less than or equal to about 1.6:1, less than or equal to about 1.5:1, less than or equal to about 1.4:1, less than or equal to about 1.3:1, less than or equal to about 1.29:1, or less than or equal to about 1.21:1.

In the semiconductor nanoparticle of an embodiment, the shell or the semiconductor nanocrystal included therein (hereinafter referred to as the semiconductor nanocrystal shell) may have a different composition from the first semiconductor nanocrystal. (Refer to FIG. 5B)

In the semiconductor nanoparticle, the shell or the semiconductor nanocrystal included therein may include zinc, selenium, and sulfur (or a zinc chalcogenide including zinc, selenium, and sulfur). In an embodiment, the shell may or may not include tellurium. The shell (or each layer in the multilayer shell described herein) may be a gradient alloy having a composition that varies in the radial direction. In an embodiment, the amount of sulfur within the semiconductor nanocrystal shell may increase toward the surface of the semiconductor nanoparticle. For example, in the shell, the amount of sulfur may have a concentration gradient that increases with distance from the core.

The shell may be a multilayer shell including a plurality of layers. In a multilayer shell, adjacent layers may include semiconductor materials of different compositions. The multilayer shell may include a middle shell layer on the core (e.g., directly on the core) and an outer shell layer on the middle shell layer. In other words, the second semiconductor nanocrystal (or the intermediate shell layer) may be disposed between the first semiconductor nanocrystal (or the core) and the third semiconductor nanocrystal (or the outer layer). (Refer to FIG. 5C)

In an embodiment, the semiconductor nanocrystal shell may include a second semiconductor nanocrystal (or an intermediate shell layer including the same) including a second zinc chalcogenide including zinc and selenium, and a third semiconductor nanocrystal (or an outer layer including the same) including a third zinc chalcogenide including zinc and sulfur. The second zinc chalcogenide may have a different composition from the third zinc chalcogenide.

The intermediate shell layer or the second semiconductor nanocrystal may include zinc, selenium, and optionally sulfur. The second zinc chalcogenide may or may not further include sulfur. The intermediate shell layer or the second semiconductor nanocrystal may include ZnSe, ZnSeS, or a combination thereof. The outer shell layer or the third semiconductor nanocrystal may include zinc, sulfur, and optionally selenium. The outer shell layer or the third semiconductor nanocrystal may include ZnS, ZnSSe, or a combination thereof. The third zinc chalcogenide may or may not further include selenium. The outer shell layer may be an outermost layer of the semiconductor nanoparticle.

In the semiconductor nanoparticle of an embodiment, a thickness of the second semiconductor nanocrystal (or the intermediate shell layer) may be greater than or equal to about 1.5 nm, greater than or equal to about 2 nm, greater than or equal to about 2.5 nm, greater than or equal to about 2.6 nm, greater than or equal to about 2.7 nm, greater than or equal to about 2.8 nm, greater than or equal to about 2.9 nm, greater than or equal to about 3 nm, greater than or equal to about 3.1 nm, greater than or equal to about 3.2 nm, greater than or equal to about 3.3 nm, greater than or equal to about 3.4 nm, greater than or equal to about 3.5 nm, greater than or equal to about 3.6 nm, greater than or equal to about 3.7 nm, greater than or equal to about 3.8 nm, greater than or equal to about 3.8 nm, greater than or equal to about 4 nm, greater than or equal to about 4.1 nm, greater than or equal to about 4.2 nm, greater than or equal to about 4.3 nm, greater than or equal to about 4.4 nm, greater than or equal to about 4.5 nm, greater than or equal to about 4.6 nm, greater than or equal to about 4.7 nm, greater than or equal to about 4.8 nm, greater than or equal to about 4.9 nm, greater than or equal to about 5 nm, greater than or equal to about 5.1 nm, or greater than or equal to about 5.1 nm. The thickness of the second semiconductor nanocrystal (or the intermediate shell layer) may be less than or equal to about 6.5 nm, less than or equal to about 6 nm, less than or equal to about 5.9 nm, less than or equal to about 5.8 nm, less than or equal to about 5.7 nm, less than or equal to about 5.6 nm, less than or equal to about 5.5 nm, less than or equal to about 5.4 nm, less than or equal to about 5.3 nm, less than or equal to about 5.2 nm, less than or equal to about 5.1 nm, less than or equal to about 5 nm, less than or equal to about 4.9 nm, less than or equal to about 4.8 nm, less than or equal to about 4.7 nm, less than or equal to about 4.6 nm, less than or equal to about 4.5 nm, less than or equal to about 4.4 nm, less than or equal to about 4.3 nm, less than or equal to about 4.2 nm, less than or equal to about 4 nm, less than or equal to about 3.4 nm, less than or equal to about 3.1 nm, less than or equal to about 2.8 nm, less than or equal to about 2.6 nm, or less than or equal to about 2.3 nm.

In the semiconductor nanoparticle of an embodiment, the thickness of the third semiconductor nanocrystal may be greater than or equal to about 0.2 nm, greater than or equal to about 0.23 nm, greater than or equal to about 0.25 nm, greater than or equal to about 0.27 nm, greater than or equal to about 0.31 nm, greater than or equal to about 0.33 nm, greater than or equal to about 0.35 nm, greater than or equal to about 0.37 nm, greater than or equal to about 0.39 nm, greater than or equal to about 0.41 nm, greater than or equal to about 0.43 nm, greater than or equal to about 0.45 nm, greater than or equal to about 0.47 nm, greater than or equal to about 0.49 nm, or greater than or equal to about 0.5 nm. The thickness of the third semiconductor nanocrystal (or the outer layer) may be less than or equal to about 3 nm, less than or equal to about 2.5 nm, less than or equal to about 1.2 nm, less than or equal to about 1.1 nm, less than or equal to about 1 nm, less than or equal to about 0.9 nm, or less than or equal to about 0.8 nm.

In the semiconductor nanoparticle of an embodiment, the thickness of the semiconductor nanocrystal shell may be greater than or equal to about 1.5 nm, greater than or equal to about 2 nm, greater than or equal to about 2.5 nm, greater than or equal to about 3 nm, greater than or equal to about 3.5 nm, greater than or equal to about 3.8 nm, greater than or equal to about 3.9 nm, greater than or equal to about 4 nm, greater than or equal to about 4.2 nm, greater than or equal to about 4.5 nm, greater than or equal to about 4.8 nm, greater than or equal to about 5 nm, greater than or equal to about 5.2 nm, greater than or equal to about 5.4 nm, or greater than or equal to about 5.5 nm. The thickness of the semiconductor nanocrystal shell may be less than or equal to about 20 nm, less than or equal to about 15 nm, less than or equal to about 10 nm, less than or equal to about 8 nm, less than or equal to about 7 nm, less than or equal to about 6 nm, less than or equal to about 5.7 nm, less than or equal to about 5.5 nm, less than or equal to about 5 nm, or less than or equal to about 4.5 nm.

In the semiconductor nanoparticle of an embodiment, a molar ratio (Se:(Se+S)) of selenium to the total sum of selenium and sulfur may be greater than or equal to about 0.55:1, greater than or equal to about 0.56:1, greater than or equal to about 0.565:1, greater than or equal to about 0.57:1, greater than or equal to about 0.575:1, greater than or equal to about 0.58:1, greater than or equal to about 0.585:1, greater than or equal to about 0.59:1, greater than or equal to about 0.595:1, greater than or equal to about 0.6:1, greater than or equal to about 0.61:1, greater than or equal to about 0.62:1, greater than or equal to about 0.63:1, greater than or equal to about 0.64:1, or greater than or equal to about 0.65:1. The molar ratio (Se:(Se+S)) of selenium to the total sum of selenium and sulfur may be less than or equal to about 0.99:1, less than or equal to about 0.97:1, less than or equal to about 0.95:1, less than or equal to about 0.94:1, less than or equal to about 0.92:1, less than or equal to about 0.88:1, less than or equal to about 0.86:1, less than or equal to about 0.84:1, less than or equal to about 0.82:1, less than or equal to about 0.78:1, less than or equal to about 0.76:1, less than or equal to about 0.74:1, less than or equal to about 0.72:1, less than or equal to about 0.7:1, less than or equal to about 0.68:1, less than or equal to about 0.66:1, less than or equal to about 0.64:1, less than or equal to about 0.62:1, less than or equal to about 0.61:1, less than or equal to about 0.6:1, less than or equal to about 0.58:1, or less than or equal to about 0.56:1.

In the semiconductor nanoparticle, a molar ratio (Te:S) of tellurium to sulfur may be greater than or equal to about 0.005:1, greater than or equal to about 0.0056:1, greater than or equal to about 0.0059:1, greater than or equal to about 0.006:1, greater than or equal to about 0.007:1, greater than or equal to about 0.008:1, greater than or equal to about 0.009:1, or greater than or equal to about 0.01:1. The molar ratio (Te:S) of tellurium to sulfur may be less than or equal to about 0.1:1, less than or equal to about 0.09:1, less than or equal to about 0.08:1, less than or equal to about 0.07:1, less than or equal to about 0.06:1, less than or equal to about 0.05:1, less than or equal to about 0.04:1, less than or equal to about 0.03:1, less than or equal to about 0.02:1, less than or equal to about 0.015:1, less than or equal to about 0.013:1, less than or equal to about 0.012:1, less than or equal to about 0.011:1, or less than or equal to about 0.01:1.

In the semiconductor nanoparticle, a molar ratio (Te:Se) of tellurium to selenium may be less than or equal to about 0.01:1, less than or equal to about 0.009:1, less than or equal to about 0.008:1, less than or equal to about 0.007:1, less than or equal to about 0.006:1, less than or equal to about 0.005:1, less than or equal to about 0.004:1, less than or equal to about 0.003:1, or less than or equal to about 0.002:1. The molar ratio (Te:Se) of tellurium to selenium may be greater than or equal to about 0.0001:1, greater than or equal to about 0.00015:1, greater than or equal to about 0.0002:1, greater than or equal to about 0.00025:1, greater than or equal to about 0.0003:1, greater than or equal to about 0.00035:1, greater than or equal to about 0.0004:1, greater than or equal to about 0.00045:1, greater than or equal to about 0.0005:1, greater than or equal to about 0.00055:1, greater than or equal to about 0.006:1, greater than or equal to about 0.00065:1, greater than or equal to about 0.0007:1, greater than or equal to about 0.00075:1, greater than or equal to about 0.0008:1, greater than or equal to about 0.00085:1, greater than or equal to about 0.0009:1, greater than or equal to about 0.00095:1, greater than or equal to about 0.001:1, greater than or equal to about 0.0015:1, greater than or equal to about 0.002:1, greater than or equal to about 0.0025:1, greater than or equal to about 0.003:1, greater than or equal to about 0.0035:1, greater than or equal to about 0.004:1, greater than or equal to about 0.0045:1, greater than or equal to about 0.005:1, greater than or equal to about 0.0055:1, greater than or equal to about 0.006:1, greater than or equal to about 0.0065:1, or greater than or equal to about 0.007:1. In the semiconductor nanoparticle of an embodiment, the molar ratio (Te:Se) of tellurium to selenium may be about 0.001:1 to about 0.009:1, about 0.002:1 to about 0.008:1, about 0.003:1 to about 0.007:1, about 0.004:1 to about 0.006:1, about 0.0045:1 to about 0.0055:1, or a combination thereof.

In the semiconductor nanoparticle, a molar ratio (Te:Zn) of tellurium to zinc may be less than or equal to about 0.009:1, less than or equal to about 0.0085:1, less than or equal to about 0.008:1, less than or equal to about 0.0075:1, less than or equal to about 0.007:1, less than or equal to about 0.0065:1, less than or equal to about 0.006:1, less than or equal to about 0.0055:1, less than or equal to about 0.005:1, less than or equal to about 0.0045:1, or less than or equal to about 0.004:1. The molar ratio (Te:Zn) of tellurium to zinc may be greater than or equal to about 0.0001:1, greater than or equal to about 0.0003:1, greater than or equal to about 0.0005:1, greater than or equal to about 0.0007:1, greater than or equal to about 0.0009:1, greater than or equal to about 0.001:1, greater than or equal to about 0.0012:1, greater than or equal to about 0.0014:1, greater than or equal to about 0.0016:1, greater than or equal to about 0.0018:1, greater than or equal to about 0.0019:1, greater than or equal to about 0.002:1, greater than or equal to about 0.0021:1, greater than or equal to about 0.0022:1, greater than or equal to about 0.0023:1, greater than or equal to about 0.0024:1, greater than or equal to about 0.0025:1, greater than or equal to about 0.0026:1, greater than or equal to about 0.0027:1, greater than or equal to about 0.0028:1, greater than or equal to about 0.0029:1, greater than or equal to about 0.003:1, greater than or equal to about 0.0031:1, greater than or equal to about 0.0032:1, greater than or equal to about 0.0033:1, greater than or equal to about 0.0034:1, greater than or equal to about 0.0035:1, greater than or equal to about 0.0036:1, greater than or equal to about 0.0037:1, greater than or equal to about 0.0038:1, greater than or equal to about 0.0039:1, or greater than or equal to about 0.004:1.

In the semiconductor nanoparticle, a molar ratio (Se:Zn) of Se to Zn may be less than about 1:1, for example, less than or equal to about 0.7:1, less than or equal to about 0.6:1, less than or equal to about 0.55:1, less than or equal to about 0.5:1, less than or equal to about 0.45:1, or less than or equal to about 0.4:1. The molar ratio (Se:Zn) of Se to Zn may be greater than or equal to about 0.1:1, for example, greater than or equal to about 0.2:1, greater than or equal to about 0.3:1, greater than or equal to about 0.4:1, greater than or equal to about 0.45:1, greater than or equal to about 0.46:1, greater than or equal to about 0.48:1, greater than or equal to about 0.5:1, greater than or equal to about 0.51:1, greater than or equal to about 0.52:1, greater than or equal to about 0.53:1, greater than or equal to about 0.54:1, greater than or equal to about 0.55:1, greater than or equal to about 0.56:1, greater than or equal to about 0.57:1, greater than or equal to about 0.58:1, greater than or equal to about 0.59:1, or greater than or equal to about 0.6:1.

In the semiconductor nanoparticle, the molar ratio ((S+Se):Zn) of Se+S to zinc may be greater than or equal to about 0.5:1, greater than or equal to about 0.6:1, greater than or equal to about 0.7:1, greater than or equal to about 0.8:1, greater than or equal to about 0.81:1, greater than or equal to about 0.82:1, greater than or equal to about 0.83:1, greater than or equal to about 0.84:1, greater than or equal to about 0.85:1, greater than or equal to about 0.86:1, greater than or equal to about 0.87:1, greater than or equal to about 0.88:1, greater than or equal to about 0.89:1, greater than or equal to about 0.9:1, greater than or equal to about 0.91:1, greater than or equal to about 0.92:1, greater than or equal to about 0.93:1, greater than or equal to about 0.94:1, greater than or equal to about 0.95:1, greater than or equal to about 0.96:1, greater than or equal to about 0.97:1, greater than or equal to about 0.98:1, greater than or equal to about 0.99:1, or greater than or equal to about 1:1. In the semiconductor nanoparticle, the molar ratio ((S+Se):Zn) of Se+S to zinc may be less than or equal to about 1.5:1, less than or equal to about 1.2:1, less than or equal to about 1:1, less than or equal to about 0.95:1, less than or equal to about 0.92:1, less than or equal to about 0.87:1, less than or equal to about 0.86:1, less than or equal to about 0.85:1, or less than or equal to about 0.83:1.

In the semiconductor nanoparticle, the molar ratio (S:Se) of sulfur to selenium may be less than or equal to about 0.8:1, less than or equal to about 0.77:1, less than or equal to about 0.75:1, less than or equal to about 0.73:1, less than or equal to about 0.7:1, less than or equal to about 0.69:1, less than or equal to about 0.68:1, less than or equal to about 0.67:1, less than or equal to about 0.66:1, less than or equal to about 0.65:1, less than or equal to about 0.64:1, less than or equal to about 0.63:1, less than or equal to about 0.62:1, or less than or equal to about 0.61:1. In the semiconductor nanoparticle of an embodiment, the molar ratio (S:Se)_of sulfur to selenium may be greater than or equal to about 0.3:1, greater than or equal to about 0.35:1, greater than or equal to about 0.4:1, greater than or equal to about 0.45:1, greater than or equal to about 0.5:1, greater than or equal to about 0.55:1, greater than or equal to about 0.59:1, greater than or equal to about 0.6:1, greater than or equal to about 0.62:1, greater than or equal to about 0.64:1, greater than or equal to about 0.65:1, greater than or equal to about 0.67:1, greater than or equal to about 0.7:1, greater than or equal to about 0.74:1, or greater than or equal to about 0.76:1.

In this specification, the molar ratio between the elements may be confirmed by appropriate analytical methods (e.g., inductively coupled plasma-atomic emission spectroscopy (ICP-AES), X-ray photoelectron spectroscopy (XPS), transmission electron microscopy-energy dispersive spectroscopy (TEM-EDX), scanning electron microscopy-energy dispersive spectroscopy (SEM-EDX), X-ray fluorescence (XRF), etc.).

The semiconductor nanoparticle of an embodiment may have the particle sizes described herein. The particle size may be a diameter or an equivalent diameter calculated assuming a sphere. The particle size of semiconductor nanoparticle may be confirmed by appropriate analytical methods such as electron microscopy analysis. The (average) size of the above semiconductor nanoparticle(s) may be greater than or equal to about 8 nm, greater than or equal to about 9 nm, greater than or equal to about 10 nm, greater than or equal to about 11 nm, greater than or equal to about 11.5 nm, greater than or equal to about 12 nm, greater than or equal to about 12.5 nm, greater than or equal to about 12.8 nm, greater than or equal to about 13 nm, greater than or equal to about 13.5 nm, greater than or equal to about 14 nm, or greater than or equal to about 14.2 nm. The (average) size of the nanoparticle(s) may be less than or equal to about 50 nm, for example, less than or equal to about 40 nm, less than or equal to about 35 nm, less than or equal to about 29 nm, less than or equal to about 28 nm, less than or equal to about 27 nm, less than or equal to about 26 nm, less than or equal to about 25 nm, less than or equal to about 24 nm, less than or equal to about 23 nm, less than or equal to about 22 nm, less than or equal to about 21 nm, less than or equal to about 20 nm, less than or equal to about 19 nm, less than or equal to about 18 nm, less than or equal to about 17.5 nm, less than or equal to about 17 nm, less than or equal to about 16.5 nm, less than or equal to about 16 nm, less than or equal to about 15.5 nm, less than or equal to about 15 nm, less than or equal to about 14.5 nm, less than or equal to about 14 nm, less than or equal to about 13.5 nm, less than or equal to about 13 nm, less than or equal to about 12.5 nm, less than or equal to about 12 nm, or less than or equal to about 11.5 nm. The average may be a mean. The mean may be a median. The numerical values set forth in this specification may include approximate values.

The semiconductor nanoparticle produced in the method of an embodiment may exhibit an improved luminescent property (e.g., quantum efficiency or absolute quantum efficiency of greater than or equal to about 90%, greater than or equal to about 92%, greater than or equal to about 94%, greater than or equal to about 96%, greater than or equal to about 97%, greater than or equal to about 98%, greater than or equal to about 99%, or greater than or equal to about 99.5%) while having a further reduced size by including the first semiconductor nanocrystal synthesized according to the method described herein. The semiconductor nanoparticle of an embodiment may have an (average) particle size of less than or equal to about 10.9 nm, less than or equal to about 10.7 nm, less than or equal to about 10.5 nm, less than or equal to about 10.3 nm, less than or equal to about 10.1 nm, less than or equal to about 9.9 nm, less than or equal to about 9.7 nm, less than or equal to about 9.5 nm, less than or equal to about 9.3 nm, less than or equal to about 9.1 nm, less than or equal to about 9 nm, less than or equal to about 8.9 nm, less than or equal to about 8.8 nm, or less than or equal to about 8.7 nm. The semiconductor nanoparticle of an embodiment may have a particle size distribution (or standard deviation of particle size) of less than or equal to about 15%, less than or equal to about 14%, less than or equal to about 13%, less than or equal to about 12%, or less than or equal to about 11%. The particle size distribution may greater than or equal to about 1%, greater than or equal to about 5%, or greater than or equal to about 7%.

The size of the particle may be easily and reproducibly determined (according to the manual provided by the manufacturer, etc.) from a photograph of the particle obtained by electron microscopy (e.g., scanning electron microscopy or transmission electron microscopy) analysis using a known or commercially available image analysis tool (e.g., Image J). The image analysis tool and measurement condition are not particularly limited.

In an embodiment, the semiconductor nanoparticle, the light emitting layer including the semiconductor nanoparticle, or the electroluminescent device may be configured to emit blue light. For example, the semiconductor nanoparticle may emit blue light upon photoexcitation or voltage application. The peak emission wavelength (maximum electroluminescent peak wavelength or maximum photoluminescent peak wavelength) of the blue light or semiconductor nanoparticle may be in a range of greater than or equal to about 450 nm, greater than or equal to about 452 nm, greater than or equal to about 455 nm, greater than or equal to about 457 nm, greater than or equal to about 460 nm, greater than or equal to about 465 nm, greater than or equal to about 470 nm, or greater than or equal to about 477 nm and less than or equal to about 480 nm (e.g., less than or equal to about 470 nm, less than or equal to about 465 nm, less than or equal to about 460 nm, or less than or equal to about 455 nm).

The photoluminescent peak wavelength or electroluminescent peak wavelength of the semiconductor nanoparticle or the light emitting layer may be greater than or equal to about 455 nm, greater than or equal to about 456 nm, greater than or equal to about 457 nm, greater than or equal to about 458 nm, greater than or equal to about 459 nm, greater than or equal to about 460 nm, greater than or equal to about 461 nm, greater than or equal to about 462 nm, greater than or equal to about 463 nm, greater than or equal to about 464 nm, greater than or equal to about 465 nm, greater than or equal to about 466 nm, greater than or equal to about 467 nm, greater than or equal to about 468 nm, greater than or equal to about 469 nm, or greater than or equal to about 470 nm. The (photo) luminescent peak wavelength of the semiconductor nanoparticle or the blue light may be less than or equal to about 480 nm, less than or equal to about 479 nm, less than or equal to about 478 nm, less than or equal to about 477 nm, less than or equal to about 476 nm, less than or equal to about 475 nm, less than or equal to about 474 nm, less than or equal to about 473 nm, less than or equal to about 471 nm, or less than or equal to about 470 nm. The photoluminescent peak wavelength is the peak emission wavelength of light emitted by semiconductor nanoparticle or a light emitting layer including the same upon photoexcitation. The electroluminescent peak wavelength is the peak emission wavelength of light emitted by semiconductor nanoparticle or a light emitting layer including the same when voltage is applied.

The semiconductor nanoparticle of the above embodiment, when irradiated with light in a solution state or manufactured as a luminescent film, may exhibit a quantum yield (e.g., absolute quantum yield) of greater than about 75%, for example, greater than or equal to about 76%, greater than or equal to about 77%, greater than or equal to about 78%, greater than or equal to about 79%, greater than or equal to about 80%, greater than or equal to about 81%, greater than or equal to about 82%, greater than or equal to about 83%, greater than or equal to about 84%, greater than or equal to about 85%, greater than or equal to about 86%, greater than or equal to about 87%, greater than or equal to about 88%, or greater than or equal to about 89%. The semiconductor nanoparticle may exhibit a quantum yield in the range of about 76% to about 100%, about 80% to about 99%, about 84% to about 97%, about 86% to about 96%, about 87% to about 95%, about 88% to about 94%, about 89% to about 93%, about 90% to about 92%, or a combination thereof. The quantum yield may be absolute quantum yield or relative quantum yield.

The semiconductor nanoparticle of an embodiment may exhibit a (maximum) luminescent peak having a full width at half maximum of a desired level when voltage is applied or when light is excited. The full width at half maximum may be in a range of about 5 nm to about 55 nm, about 8 nm to about 54 nm, about 9 nm to about 53 nm, about 10 nm to about 52 nm, about 11 nm to about 51 nm, about 12 nm to about 50 nm, about 13 nm to about 49 nm, about 14 nm to about 48 nm, about 15 nm to about 47 nm, about 16 nm to about 46 nm, about 17 nm to about 45 nm, about 18 nm to about 44 nm, about 19 nm to about 43 nm, about 20 nm to about 42 nm, about 21 nm to about 41 nm, about 22 nm to about 40 nm, about 25 nm to about 35 nm, about 28 nm to about 32 nm, or a combination thereof.

The semiconductor nanoparticle is configured to emit a first light when voltage is applied, and the electroluminescent peak wavelength of the first light or the semiconductor nanoparticle may be greater than or equal to about 460 nm, or greater than or equal to about 461 nm and less than or equal to about 490 nm.

The core or the semiconductor nanoparticle may exhibit a reduced level of trap emission. In an embodiment, the core or the semiconductor nanoparticle may have a ratio of the intensity at the trap emission wavelength to the intensity at the peak emission wavelength in the photoluminescence spectrum of less than or equal to about 0.24:1, less than or equal to about 0.23:1, less than or equal to about 0.19:1, less than or equal to about 0.18:1, less than or equal to about 0.15:1, less than or equal to about 0.14:1, less than or equal to about 0.13:1, or less than or equal to about 0.12:1. The trap emission wavelength may be 500 nm or (peak emission wavelength+50 nm).

In an embodiment, the semiconductor nanoparticle may further include a halogen (e.g., fluorine, chlorine, or a combination thereof).

In an embodiment, the semiconductor nanoparticle may be produced according to a method described herein. In an embodiment, the method for producing semiconductor nanoparticle includes,
preparing a first semiconductor nanocrystal including zinc, tellurium, and selenium; and
heating a second zinc precursor and a chalcogen precursor in a second organic solvent in the presence of the first semiconductor nanocrystal and an organic ligand (e.g., a second organic ligand) to obtain a semiconductor nanoparticle (e.g., including the first semiconductor nanocrystal and the second semiconductor nanocrystal),
wherein the preparation of the first semiconductor nanocrystal includes:
heating a first solution including a first zinc precursor, a first selenium precursor a tellurium precursor, and optionally a first ligand in a first organic solvent at a reaction temperature, for example, for a first time period; and
further adding an additive to the heated first solution,
wherein the additive includes a second selenium precursor, and the additive does not include tellurium. The additive may include a zinc compound, hydrofluoric acid (HF), or a combination thereof. Details of the semiconductor nanoparticle and the first semiconductor nanocrystal are as described herein.

By the method of an embodiment, the first semiconductor nanocrystal may have a tellurium distribution concentrated in the central portion as defined herein, and including the first semiconductor nanocrystal thus produced, for example, as a core, can reduce trap emission and improve luminous efficiency and life-span characteristics in an EL device.

In an embodiment, the production of the first semiconductor nanocrystal may be accomplished by utilizing the difference in reactivity of Te and Se precursors, controlling the distribution of Te by a split (portion-wise) injection of some precursors, or a combination thereof. According to the method of an embodiment, a nucleus (or central portion) of a first semiconductor nanocrystal can be formed by heating a first solution including a first zinc precursor, a first selenium precursor, and a tellurium precursor in a first organic solvent at a reaction temperature for a first time period (e.g., a time for nucleation). In the nucleus forming process of these first semiconductor nanocrystals, the reaction system includes the Zn precursor, the Te precursor, and the Se precursor, thereby providing ZnTeSe nuclei with a desired (e.g., a relatively high) Te amount (e.g., the nucleus or central portion, A, having a composition of ZnTeₐSe₁₋ₐ in FIG. 5A). These ZnTeSe nuclei can exhibit a first absorption peak of less than or equal to about 380 nm when confirmed by UV-Vis absorption spectrum analysis. Additionally, the UV-Vis absorption spectrum of these ZnTeSe nuclei may have a valley depth (VD) of greater than or equal to about 0.01, or greater than or equal to about 0.05, or greater than or equal to about 0.09, or greater than or equal to about 0.1, as defined by the following equation:

$$1 - ( {Abs}_{valley} / {Abs}_{first} ) = VD$$

wherein, Abs_{first} is an absorption at the first absorption peak, and Abs_{valley} is the absorption at the lowest point of the valley adjacent to the first absorption peak.

The valley depth may be less than or equal to about 0.3, less than or equal to about 0.2, or less than or equal to about 0.15.

The first time period may be in the range of less than or equal to about 45 minutes, less than or equal to about 40 minutes, less than or equal to about 35 minutes, about 1 minute to about 30 minutes, about 2 minutes to about 25 minutes, about 3 minutes to about 20 minutes, about 4 minutes to about 18 minutes, about 5 minutes to about 15 minutes, about 6 minutes to about 14 minutes, about 7 minutes to about 13 minutes, about 8 minutes to about 12 minutes, about 9 minutes to about 12 minutes, about 10 minutes to about 11 minutes, or a combination thereof.

In an embodiment, a mixture including a first selenium precursor and a tellurium precursor may be added into a reaction medium including a zinc precursor to form a first solution. The mixture may further include, for example, an additional organic ligand (e.g., an aryl phosphine compound such as diphenylphosphine).

The heated first solution may include a ZnTeSe nucleus (e.g., a ZnTeSe nucleus with a high Te amount or a nucleus or central portion having a composition of ZnTeₐSe₁₋ₐ in FIG. 5A), to which an additive may be added. After addition of the additive, the first solution can be further heated at the reaction temperature for an additional period of time. The additive includes a second selenium precursor and optionally a zinc compound, hydrofluoric acid, or a combination thereof, wherein the additive does not include tellurium.

According to the method of an embodiment, a Se precursor (and optionally a Zn precursor) are additionally injected to grow the first semiconductor nanocrystal to a desired core size, and the first semiconductor nanocrystal thus produced can have an element concentration distribution (for example, a tellurium distribution index (%) as described herein) in which the Te amount of the central portion (i.e., ZnTeSe) nucleus is higher than the Te amount in the adjacent surface portion, and thus the Te:Se molar ratio in the entire first semiconductor nanocrystal may be lower than that in the ZnSeTe nucleus. (Refer to FIG. 5A)

Without wishing to be bounded by a particular theory, it is believed that the concentration of Te inside the crystal within the first semiconductor nanocrystal, as in the present embodiment, may contribute to reducing core surface oxidation due to Te exposure and the occurrence of interface defects in the core/shell structure. The semiconductor nanoparticle produced according to the production method of an embodiment can exhibit optical properties with the molar ratio described herein. The semiconductor nanoparticle having a core with increased internal Te concentration, as in the present embodiment, may exhibit improved performance (EQE, life-span) in electroluminescent devices.

In producing the first semiconductor nanocrystal according to an embodiment, the second selenium precursor may be the same as or different from the first selenium precursor.

In the method, an amount of the second selenium precursor may be, per 1 mole of the first selenium precursor, greater than or equal to about 0.05 moles, greater than or equal to about 0.06 moles, greater than or equal to about 0.07 moles, greater than or equal to about 0.08 moles, greater than or equal to about 0.09 moles, greater than or equal to about 0.1 moles, greater than or equal to about 0.2 moles, greater than or equal to about 0.25 moles, greater than or equal to about 0.27 moles, greater than or equal to about 0.3 moles, greater than or equal to about 0.35 moles, greater than or equal to about 0.4 moles, greater than or equal to about 0.5 moles, greater than or equal to about 0.6 moles, greater than or equal to about 0.7 moles, greater than or equal to about 0.8 moles, greater than or equal to about 0.9 moles, greater than or equal to about 1 mole, greater than or equal to about 1.3 moles, greater than or equal to about 1.5 moles, greater than or equal to about 1.7 moles, greater than or equal to about 1.9 moles, greater than or equal to about 2 moles, greater than or equal to about 2.5 moles, greater than or equal to about 3 moles, greater than or equal to about 3.5 moles, greater than or equal to about 4 moles, greater than or equal to about 4.5 moles, greater than or equal to about 5 moles, greater than or equal to about 5.5 moles, greater than or equal to about 6 moles, greater than or equal to about 6.5 moles, greater than or equal to about 7 moles, greater than or equal to about 7.5 moles, greater than or equal to about 8 moles, greater than or equal to about 8.5 moles, greater than or equal to about 9 moles, or greater than or equal to about 9.5 moles. In the method, the amount of the second selenium precursor may be, per 1 mole of the first selenium precursor, less than or equal to about 20 moles, less than or equal to about 18 moles, less than or equal to about 16 moles, less than or equal to about 14 moles, less than or equal to about 12 moles, less than or equal to about 10 moles, less than or equal to about 9 moles, less than or equal to about 8 moles, less than or equal to about 7 moles, less than or equal to about 6 moles, less than or equal to about 5 moles, less than or equal to about 4 moles, less than or equal to about 3 moles, less than or equal to about 2 moles, less than or equal to about 1 mole, less than or equal to about 0.9 moles, less than or equal to about 0.7 moles, less than or equal to about 0.5 moles, less than or equal to about 0.3 moles, or less than or equal to about 0.1 moles.

In an embodiment, the amount of the first selenium precursor may be greater than that of the second selenium precursor, for example, by greater than or equal to about 10%, or greater than or equal to about 20%. The second selenium precursor may be added one or more times, for example, two, three, or four or more times.

In an embodiment, the zinc compound added as an additive may be the same as or different from the zinc precursor. The zinc compound may be different from the zinc precursor. In an embodiment, the zinc compound may include a zinc carboxylate such as zinc acetate, zinc oleate, zinc myristate, zinc stearate, etc., zinc acetylacetonate, a zinc halide such as zinc chloride, zinc bromide, zinc iodide, zinc fluoride, etc., or a combination thereof. The zinc compound may be of two or more types. For specific examples of other zinc compounds, the zinc precursors described herein may be referred.

In an embodiment, the zinc precursor may include dialkylzinc. The zinc compound may include zinc carboxylate and zinc halide. The zinc halide may include zinc chloride. The additive may each be added one or more times or two or more times. In an embodiment, the additive may include a second selenium precursor; and a zinc compound, hydrofluoric acid, or a combination thereof, which may be added in a mixture or added separately. The second selenium precursor can be added at once or injected in multiple split manner.

In an embodiment, an additive (e.g., a zinc compound, hydrofluoric acid, or a combination thereof) may be added to the reaction system before the addition of the second selenium precursor or after the addition of the second selenium precursor. When the addition of the second selenium precursor is performed twice or more, it may be added after the initial or first addition of the second selenium precursor, for example, before or together with the subsequent addition of the second selenium precursor.

In the method, the total amount of the first selenium precursor and the second selenium precursor may be, per 1 mole of the tellurium precursor, greater than or equal to about 5 moles, greater than or equal to about 10 moles, greater than or equal to about 11 moles, greater than or equal to about 12 moles, greater than or equal to about 13 moles, greater than or equal to about 15 moles, greater than or equal to about 17 moles, greater than or equal to about 20 moles, greater than or equal to about 23 moles, greater than or equal to about 25 moles, greater than or equal to about 28 moles, greater than or equal to about 29 moles, greater than or equal to about 30 moles, greater than or equal to about 35 moles, greater than or equal to about 39 moles, greater than or equal to about 43 moles, greater than or equal to about 44 moles, greater than or equal to about 48 moles, greater than or equal to about 49 moles, greater than or equal to about 50 moles, greater than or equal to about 52 moles, greater than or equal to about 54 moles, greater than or equal to about 55 moles, greater than or equal to about 57 moles, greater than or equal to about 58 moles, greater than or equal to about 59 moles, or greater than or equal to about 60 moles. In the method, the total amount of the first selenium precursor and the second selenium precursor may be, per 1 mole of the tellurium precursor, less than or equal to about 65 moles, less than or equal to about 63 moles, less than or equal to about 62 moles, less than or equal to about 60 moles, less than or equal to about 58 moles, less than or equal to about 55 moles, less than or equal to about 52 moles, less than or equal to about 50 moles, less than or equal to about 47 moles, less than or equal to about 42 moles, less than or equal to about 32 moles, less than or equal to about 29 moles, less than or equal to about 27 moles, less than or equal to about 24 moles, less than or equal to about 20 moles, less than or equal to about 19 moles, less than or equal to about 18 moles, less than or equal to about 16 moles, less than or equal to about 14 moles, or less than or equal to about 12 moles. In the method, the total amount of the first selenium precursor and the second selenium precursor per 1 mole of the tellurium precursor may be in any suitable combination of the molar amounts described herein.

In the method of an embodiment, if added, the amount of the zinc compound may be appropriately adjusted in consideration of the composition and structure of the desired core. In an embodiment, the zinc compound may be present in an amount of greater than or equal to 0.05 moles, greater than or equal to about 0.1 moles, greater than or equal to about 0.3 moles, greater than or equal to about 0.5 moles, greater than or equal to about 0.7 moles, greater than or equal to about 0.9 moles, greater than or equal to about 1 mole, greater than or equal to about 1.1 moles, greater than or equal to about 1.2 moles, greater than or equal to about 1.3 moles, greater than or equal to about 1.4 moles, or greater than or equal to about 1.5 moles per 1 mole of the second selenium precursor. In an embodiment, the zinc compound may be present in an amount of less than or equal to about 10 moles, less than or equal to about 5 moles, less than or equal to about 3 moles, less than or equal to about 2 moles, less than or equal to about 1 mole, less than or equal to about 0.8 moles, or less than or equal to about 0.7 moles per 1 mole of the second selenium precursor.

In an embodiment, when used, the amount of hydrofluoric acid may be greater than or equal to about 0.001 moles, greater than or equal to about 0.005 moles, greater than or equal to about 0.01 moles, greater than or equal to about 0.05 moles, greater than or equal to about 0.1 moles, or greater than or equal to about 0.5 moles per 1 mole of the second selenium precursor. In an embodiment, when used, the amount of hydrofluoric acid may be less than or equal to about 10 moles, less than or equal to about 5 moles, less than or equal to about 3 moles, less than or equal to about 2 moles, less than or equal to about 1 mole, less than or equal to about 0.8 moles, less than or equal to about 0.7 moles, less than or equal to about 0.4 moles, less than or equal to about 0.2 moles, less than or equal to about 0.1 moles, less than or equal to about 0.05 moles, or less than or equal to about 0.03 moles per 1 mole of the second selenium precursor

In the first semiconductor nanocrystal or core formation reaction, the ratio between each precursor (e.g., molar ratio of tellurium or selenium precursor to zinc precursor) or total reaction time can be appropriately selected considering the emission wavelength of the final semiconductor nanoparticle, the reactivity of the precursor, the reaction temperature, etc. The reaction temperature for forming the first semiconductor nanocrystal may be appropriately selected. The first semiconductor nanocrystal formation reaction temperature may be greater than or equal to about 200° C., greater than or equal to about 220° C., greater than or equal to about 230° C., greater than or equal to about 240° C., greater than or equal to about 250° C., greater than or equal to about 280° C., or greater than or equal to about 290° C. The reaction temperature for forming the first semiconductor nanocrystal may be in the range of less than or equal to about 350° C., about 210° C. to about 340° C., for example, about 220° C. to about 330° C., about 230° C. to about 300° C., about 240° C. to about 290° C., or a combination thereof. The total reaction time for the formation of the first semiconductor nanocrystal may be controlled by taking into account the desired core size and the reactivity of the precursor. For example, the total reaction time may be greater than or equal to about 5 minutes, greater than or equal to about 30 minutes, or greater than or equal to about 50 minutes, but is not limited thereto. For example, the reaction time may be less than or equal to about 2 hours, but is not limited thereto. The formed core may or may not be separated from the reaction system (e.g., by non-solvent precipitation). The separated cores may be optionally washed and added to subsequent reactions.

The method of an embodiment includes forming a semiconductor nanocrystal shell on the first semiconductor nanocrystal by reacting a zinc precursor and a chalcogen precursor in the presence of the produced first semiconductor nanocrystal, thereby obtaining a semiconductor nanoparticle of an embodiment. In an embodiment, the second zinc precursor and the chalcogen precursor may be heated in a second organic solvent in the presence of the first semiconductor nanocrystal and a second organic ligand.

The chalcogen precursor (e.g., for formation of a semiconductor nanocrystal shell) may include a selenium precursor, a sulfur precursor, a tellurium precursor, or a combination thereof. The chalcogen precursor may include a selenium precursor and a sulfur precursor. When the chalcogen precursor includes two or more precursors, each precursor may be added to the reaction system taking into account the composition of the final semiconductor nanoparticle.

In the method of an embodiment, the zinc precursor, the solvent, and optionally an organic ligand may be heated (or vacuum-treated) under vacuum to a predetermined temperature (e.g., 100° C. or higher and 180° C. or lower), and the reaction system is heated to a reaction temperature for shell formation by changing to an inert gas atmosphere. The first semiconductor nanocrystal and the chalcogen precursor may be added to the reaction system. Reaction conditions such as reaction temperature and time for shell formation may be appropriately selected considering the desired shell composition.

A chalcogen precursor may be introduced simultaneously or sequentially, taking into account the final composition, to form a shell of a desired composition (e.g., having a gradient or multilayers). In an embodiment, a zinc precursor and a selenium precursor may be reacted to form a first shell layer (e.g., a middle shell layer), and then a zinc precursor and a sulfur precursor may be reacted to form a second shell layer (e.g., an outer shell layer). In an embodiment, a zinc precursor, a selenium precursor, and a sulfur precursor can react together.

In an embodiment, reacting the zinc precursor and the chalcogen precursor may include reacting the zinc precursor and the selenium precursor to form a second semiconductor nanocrystal (or intermediate shell layer), and reacting the zinc precursor and the sulfur precursor to form a third semiconductor nanocrystal (or outer shell layer) (e.g., on the intermediate shell layer).

In the formation of the semiconductor nanocrystal shell, an amount of selenium precursor used per 1 mole of zinc precursor may be greater than or equal to about 0.1 moles, greater than or equal to about 0.3 moles, greater than or equal to about 0.5 moles, greater than or equal to about 0.65 moles, greater than or equal to about 0.7 moles, greater than or equal to about 0.9 moles, greater than or equal to about 1 mole, greater than or equal to about 1.5 moles, or greater than or equal to about 2 moles and less than or equal to about 5 moles, less than or equal to about 4 moles, less than or equal to about 3 moles, less than or equal to about 2 moles, or less than or equal to about 1 mole, but is not limited thereto. In the formation of the semiconductor nanocrystal shell, an amount of sulfur precursor used per 1 mole of zinc precursor may be greater than or equal to about 0.1 moles, greater than or equal to about 0.3 moles, greater than or equal to about 0.5 moles, greater than or equal to about 0.7 moles, greater than or equal to about 0.9 moles, greater than or equal to about 1 mole, greater than or equal to about 1.3 moles, greater than or equal to about 1.5 moles, or greater than or equal to about 2 moles and less than or equal to about 5 moles, less than or equal to about 4 moles, less than or equal to about 3 moles, less than or equal to about 2 moles, or less than or equal to about 1 mole, but is not limited thereto.

When two or more chalcogen precursors are used for the formation of a semiconductor nanocrystal shell, the amount of each precursor used can be appropriately selected to control the thickness of each shell layer and the ratio therebetween as disclosed herein.

In the method of an embodiment, an amount of sulfur precursor used per 1 mole of selenium precursor may be greater than or equal to about 0.1 moles, greater than or equal to about 0.5 moles, greater than or equal to about 0.65 moles, greater than or equal to about 0.7 moles, greater than or equal to about 0.9 moles, greater than or equal to about 1 mole, greater than or equal to about 1.1 moles, greater than or equal to about 1.3 moles, greater than or equal to about 1.5 moles, greater than or equal to about 1.7 moles, or greater than or equal to about 2 moles. In the method, the amount of sulfur precursor used per 1 mole of selenium precursor may be less than or equal to about 3 moles, less than or equal to about 2.5 moles, less than or equal to about 2 moles, less than or equal to about 1.8 moles, less than or equal to about 1.6 moles, less than or equal to about 1.4 moles, less than or equal to about 1.2 moles, less than or equal to about 0.8 moles, or less than or equal to about 0.6 moles.

The addition of the chalcogen precursor (e.g., a selenium precursor or a sulfur precursor) may be done all at once or in a portion-wise manner. In the method of an embodiment, the selenium precursor may be injected in portion-wise into the reaction system (i.e., intermittently) and in equal or different aliquots two or more times (three or more times, four or more times, five or more times, six or more times, seven or more times, eight or more times, or nine or more times). In the method, the sulfur precursor may be injected into the reaction system at one time, or may be injected portion-wise in two or more portions (e.g., three or more times, four or more times, five or more times), optionally together with the zinc precursor. The selenium precursor and the sulfur precursor may be injected separately. The selenium precursor and the sulfur precursor may be injected without being mixed. In an embodiment, the portion-wise injection of the sulfur precursor may be initiated after the injection of the selenium precursor in a predetermined amount is completed.

The reaction temperature for shell formation may be greater than or equal to about 300° C., greater than or equal to about 320° C., greater than or equal to about 330° C., greater than or equal to about 340° C., greater than or equal to about 342° C., greater than or equal to about 345° C., greater than or equal to about 350° C., greater than or equal to about 355° C., or greater than or equal to about 360° C. The reaction temperature for shell formation may be less than or equal to about 380° C., less than or equal to about 370° C., less than or equal to about 360° C., less than or equal to about 355° C., or less than or equal to about 350° C.

The zinc precursor or zinc compound may include Zn metal powder, ZnO, an alkylated Zn compound (e.g., a (C2 to C30 dialkyl) zinc such as diethylzinc), Zn alkoxide (e.g., zinc ethoxide), Zn carboxylate (e.g., zinc acetate), Zn nitrate, Zn perchlorate, Zn sulfate, Zn acetylacetonate, Zn halide (e.g., zinc chloride), Zn cyanide, Zn hydroxide, zinc carbonate, zinc peroxide, or a combination thereof. Examples of zinc precursors may include dimethyl zinc, diethyl zinc, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, or a combination thereof.

The selenium precursor (or the first selenium precursor, the second selenium precursor, or a combination thereof) may include, but is not limited to, selenium-selenium-tributylphosphine (Se-TOP), selenium-trioctylphosphine (Se-TOP), triphenylphosphine (Se-TPP), selenium-diphenylphosphine (Se-DPP), or a combination thereof.

The tellurium precursor may include, but is not limited to, tellurium-tributylphosphine (Te-TBP), tellurium-triphenylphosphine (Te-TPP), tellurium-diphenylphosphine (Te-DPP), or a combination thereof.

The sulfur precursor may include hexanethiol, octanethiol, decanethiol, dodecanethiol, hexadecanethiol, mercapto propyl silane, sulfur-trioctylphosphine (S-TOP), sulfur-tributylphosphine (S-TBP), sulfur-triphenylphosphine (S-TPP), sulfur-trioctylamine (S-TOA), bis(trialkylsilyl) sulfide, bis(trialkylsilylalkyl) sulfide (e.g., bis(trimethylsilylmethyl) sulfide), ammonium sulfide, sodium sulfide, or a combination thereof.

The organic solvent (the first organic solvent, the second organic solvent, or a combination thereof) may include a C6 to C22 primary amine such as oleyl amine or hexadecylamine, a C6 to C22 secondary amine such as dioctylamine, a C6 to C40 tertiary amine such as a trioctyl amine, a nitrogen-containing heterocyclic compound such as pyridine, a C6 to C40 olefin such as octadecene, a C6 to C40 aliphatic hydrocarbon such as hexadecane, octadecane, or squalane, an aromatic hydrocarbon substituted with a C6 to C30 alkyl group such as phenyldodecane, phenyltetradecane, or phenyl hexadecane, a primary, secondary, or tertiary phosphine (e.g., trioctylphosphine) substituted with a, e.g., at least one (e.g., 1, 2, or 3), C6 to C22 alkyl group, a primary, secondary, or tertiary phosphine oxide (e.g., trioctylphosphine oxide) substituted with a (e.g., 1, 2, or 3) C6 to C22 alkyl group, a C12 to C22 aromatic ether such as phenyl ether or benzyl ether, or a combination thereof.

The semiconductor nanoparticle may include, for example, an organic ligand (a second organic ligand) on the surface. The organic ligand coordinates the surface of the produced nanocrystals, and not only enables the nanocrystals to be well dispersed in the solution phase, but can also affect the luminescent and electrical properties. The organic ligand (e.g., a first organic ligand and/or a second organic ligand) may include RCOOH, RNH₂, R₂NH, R₃N, RSH, RH₂PO, R₂HPO, R₃PO, RH₂P, R₂HP, R₃P, ROH, RCOOR′, RPO(OH)₂, R₂PO(OH), or a combination thereof (wherein R and R′ each independently include a substituted or unsubstituted C1 to C40 (or C3 to C24) aliphatic hydrocarbon group, or a substituted or unsubstituted C6 to C40 (or C6 to C24) aromatic hydrocarbon group, or a combination thereof). The ligand may be used alone or as a mixture of two or more compounds.

Specific examples of the organic ligand compound may include methane thiol, ethane thiol, propane thiol, butane thiol, pentane thiol, hexane thiol, octane thiol, dodecane thiol, hexadecane thiol, octadecane thiol, benzyl thiol; methyl amine, ethyl amine, propyl amine, butyl amine, pentyl amine, hexyl amine, octyl amine, dodecyl amine, hexadecyl amine, oleyl amine, octadecyl amine, dimethyl amine, diethyl amine, dipropyl amine; methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid, palmitic acid, stearic acid; phosphine such as methyl phosphine, ethyl phosphine, propyl phosphine, butyl phosphine, pentyl phosphine, tributylphosphine, or trioctylphosphine; a phosphine oxide compound such as methyl phosphine oxide, ethyl phosphine oxide, propyl phosphine oxide, butyl phosphine oxide, or trioctylphosphine oxide; a diphenyl phosphine or triphenyl phosphine compound, or an oxide compound thereof; phosphonic acid, and the like, but are not limited thereto. The organic ligand compound may be used alone or in a mixture of two or more compounds. In an embodiment, the organic ligand compound may be a combination of RCOOH and amine (e.g., RNH₂, R₂NH, R₃N, or a combination thereof).

After completion of the reaction, when a nonsolvent is added to the reaction product, nanocrystal particles coordinated with the ligand compound may be separated. The nonsolvent may be a polar solvent that is miscible with the solvent used in the core formation reaction, shell formation reaction, or a combination thereof and is not capable of dissolving the prepared nanocrystals. The nonsolvent may be selected depending on the solvent used in the reaction and may include, for example, acetone, ethanol, butanol, isopropanol, ethanediol, water, tetrahydrofuran (THF), dimethylsulfoxide (DMSO), diethylether, formaldehyde, acetaldehyde, a solvent having a similar solubility parameter to the foregoing non-solvents, or a combination thereof. The semiconductor nanocrystal particle may be separated through centrifugation, sedimentation, chromatography, or distillation. The separated nanocrystal particle may be added to a washing solvent and washed, if needed. The washing solvent has no particular limit and may not dissolve the nanocrystal particle and may have a similar solubility parameter to that of the ligand and may, for example, include hexane, heptane, octane, chloroform, toluene, benzene, and the like.

The semiconductor nanoparticle of an embodiment may be non-dispersible or insoluble in water, the aforementioned nonsolvent, or a combination thereof.

The semiconductor nanoparticle of an embodiment may be dispersed in the aforementioned organic solvent. In an embodiment, the aforementioned semiconductor nanoparticle may be dispersed in substituted or unsubstituted C6 to C40 aliphatic hydrocarbon, substituted or unsubstituted C6 to C40 aromatic hydrocarbon, or a combination thereof.

In the light emitting device, the thickness of the light emitting layer can be appropriately selected. In an embodiment, the light emitting layer may include a monolayer(s) of nanoparticles. In an embodiment, the emitting layer may include one or more monolayers of nanoparticles, for example, two or more layers, three or more layers, or four or more layers, and 20 layers or less, 10 layers or less, 9 layers or less, 8 layers or less, 7 layers or less, or 6 layers or less. The light emitting layer may have a thickness of greater than or equal to about 5 nm, for example, greater than or equal to about 10 nm, greater than or equal to about 20 nm, or greater than or equal to about 30 nm and less than or equal to about 200 nm, for example, 150 nm, less than or equal to about 100 nm, less than or equal to about 90 nm, less than or equal to about 80 nm, less than or equal to about 70 nm, less than or equal to about 60 nm, or less than or equal to about 50 nm. The light emitting layer may have a thickness of, for example, about 10 nm to about 150 nm, about 20 nm to about 100 nm, or about 30 nm to about 50 nm.

The forming of the light emitting layer may be performed by obtaining a composition including the nanoparticles (configured to emit the desired light) and applying or depositing the same on a substrate or a charge auxiliary layer by an appropriate method (e.g., by spin coating, inkjet printing, etc.).

In an embodiment, the light emitting layer may include a first layer including the semiconductor nanoparticle described above (hereinafter, referred to as first semiconductor nanoparticle) and a second layer adjacent to the first layer and including second semiconductor nanoparticle. Adjacent layers in a multilayer light emitting layer (e.g., the first light emitting layer and the second light emitting layer) may be configured to emit the same color (e.g., blue light). In an embodiment, the second semiconductor nanoparticle may include a zinc chalcogenide, wherein the zinc chalcogenide may include zinc, selenium, and sulfur, and the semiconductor particles may not include cadmium and may emit blue light.

The forming of a multilayer light emitting layer may include forming a layer of a semiconductor nanoparticle and contacting the formed layer with an organic solution (e.g., an alcohol solution) of, for example, a metal halide (e.g., zinc chloride) to exchange ligands of particles included within the formed layer. Alternatively, the forming of the multilayer light emitting layer may include dispersing semiconductor nanoparticle in an organic solvent, adding an organic solution (e.g., an alcoholic solution) of a metal halide (e.g., zinc chloride) thereto, to obtain ligand-exchanged particles, from which the first layer (or second layer) is formed. On the ligand-exchanged layer, a layer of semiconductor nanoparticle may be further provided. Therefore, in a multilayer structure, adjacent layers (e.g., a first light emitting layer and a second light emitting layer) may have the same or different compositions, ligands, or a combination thereof from each other. In an embodiment, the light emitting layer or the multilayer light emitting layer including two or more layers may have a halogen amount that changes in a thickness direction. In the (multilayer) light emitting layer according to an embodiment, the halogen amount may increase towards the electron auxiliary layer. In the (multilayer) light emitting layer according to an embodiment, the organic ligand amount may decrease towards the electron auxiliary layer. In the light emitting layer according to an embodiment, the halogen amount may decrease toward the electron auxiliary layer. In the (multilayer) light emitting layer according to an embodiment, the organic ligand amount may increase towards the electron auxiliary layer.

The electroluminescent device may include a charge (hole or electron) auxiliary layer between the first electrode and the second electrode (e.g., the anode and the cathode). For example, the electroluminescent device may include a hole auxiliary layer 20 or an electron auxiliary layer 40 between the first electrode 10 and the light emitting layer 30, between the second electrode 50 and the light emitting layer 30, or a combination thereof. (Refer to FIGS. 2 and 3)

The light emitting device according to an embodiment may further include a hole auxiliary layer. The hole auxiliary layer 20 is located between the first electrode 10 and the light emitting layer 30. The hole auxiliary layer 20 may include a hole injection layer, a hole transport layer (HTL), an electron blocking layer, or a combination thereof. The hole auxiliary layer 20 may be a layer of a single component or a multilayer structure in which adjacent layers include different components.

The hole auxiliary layer 20 may have a HOMO energy level that can be matched with the HOMO energy level of the light emitting layer 30 in order to enhance mobility of holes transferred from the hole auxiliary layer 20 to the light emitting layer 30. In an embodiment, the hole auxiliary layer 20 may include a hole injection layer close to the first electrode 10 and a hole transport layer close to the light emitting layer 30.

The material included in the hole auxiliary layer 20 (e.g., a hole transport layer, a hole injection layer, or an electron blocking layer) is not particularly limited, and may include, for example, poly(9,9-dioctyl-fluorene-co-N-(4)-butylphenyl)-diphenylamine) (TFB), polyarylamine, poly(N-vinylcarbazole), poly(3,4-ethylenedioxythiophene) (PEDOT), poly(3,4-ethylenedioxythiophene): polystyrene sulfonate (PEDOT:PSS), polyaniline, polypyrrole, N,N,N′,N′-tetrakis(4-methoxyphenyl)-benzidine (TPD), 4,4′-bis[N-(1-naphthyl)-N-phenyl-amino]biphenyl (α-NPD), m-MTDATA (4,4′,4″-Tris[phenyl(m-tolyl)amino]triphenylamine), 4,4′,4″-tris(N-carbazolyl)-triphenylamine (TCTA), 1,1-bis[(di-4-toylamino)phenyl]cyclohexane (TAPC), a p-type metal oxide (e.g., NiO, WO₃, MoO₃, etc.), a carbon-based material such as graphene oxide, or a combination thereof, but is not limited thereto.

In the hole auxiliary layer(s), the thickness of each layer may be appropriately selected. For example, the thickness of each layer may be greater than or equal to about 5 nm, greater than or equal to about 10 nm, greater than or equal to about 15 nm, or greater than or equal to about 20 nm and less than or equal to about 100 nm, less than or equal to about 90 nm, less than or equal to about 80 nm, less than or equal to about 70 nm, less than or equal to about 60 nm, less than or equal to about 50 nm, for example, less than or equal to about 40 nm, less than or equal to about 35 nm, or less than or equal to about 30 nm, but is not limited thereto.

The electronic auxiliary layer 40 is located between the light emitting layer 30 and the second electrode 50. The electron auxiliary layer 40 may include, for example, an electron injection layer, an electron transport layer, a hole blocking layer, or a combination thereof. The electron auxiliary layer may include, for example, an electron injection layer (EIL) to facilitate electron injection, an electron transport layer (ETL) to facilitate electron transport, a hole blocking layer (HBL) to inhibit hole transport, or a combination thereof.

In an embodiment, the electron injection layer may be disposed between the electron transport layer and the second electrode. For example, the hole blocking layer may be disposed between the emission layer and the electron transport (injection) layer, but is not limited thereto. A thickness of each layer may be appropriately selected. For example, a thickness of each layer may be greater than or equal to about 1 nm and less than or equal to about 500 nm, but is not limited thereto. The electron injection layer may be an organic layer formed by deposition. The electron transport layer may include an inorganic oxide nanoparticle or may be an organic layer formed by deposition.

The electron transport layer (ETL), electron injection layer (EIL), hole blocking layer, or a combination thereof may include, for example, 1,4,5,8-naphthalene-tetracarboxylic dianhydride (NTCDA), bathocuproine (BCP), tris[3-(3-pyridyl)-mesityl]borane (3TPYMB), LiF, tris(8-hydroxyquinoline)aluminum (Alq₃), tris(8-hydroxyquinoline)gallium (Gaq₃), tris-(8-hydroxyquinoline)indium (Inq₃), bis(8-hydroxyquinoline)zinc (Znq₂), bis(2-(2-hydroxyphenyl)benzothiazolate)zinc (Zn(BTZ)₂), bis(10-hydroxybenzo[h]quinolinato)beryllium (BeBq₂), 8-(4-(4,6-di(naphthalen-2-yl)-1,3,5-triazin-2-yl)phenyl)quinolone (ET204), 8-hydroxyquinolinato lithium (Liq), n-type metal oxide (e.g., ZnO, HfO₂, etc.), or a combination thereof, but is not limited thereto.

The electron auxiliary layer 40 may include an electron transport layer. The electron transport layer may include a plurality of nanoparticles. The plurality of nanoparticles may include a metal oxide including zinc.

The metal oxide may include zinc oxide, zinc magnesium oxide, or a combination thereof. The metal oxide may include Zn₁₋ₓ MₓO (wherein, M is Mg, Ca, Zr, W, Li, Ti, Y, Al, or a combination thereof and 0≤x≤0.5). In an embodiment, M in Zn₁₋ₓ MₓO may be magnesium (Mg). In an embodiment, x in Zn₁₋ₓ MₓO may be greater than or equal to about 0.01 and less than or equal to about 0.3, for example, less than or equal to about 0.25, less than or equal to about 0.2, or less than or equal to about 0.15.

The absolute value of the LUMO of the above-mentioned nanoparticles included in the emitting layer may be greater or smaller than the absolute value of the LUMO of the metal oxide. The average size of the nanoparticles may be greater than or equal to about 1 nm, for example, greater than or equal to about 1.5 nm, greater than or equal to about 2 nm, greater than or equal to about 2.5 nm, or greater than or equal to about 3 nm and less than or equal to about 10 nm, less than or equal to about 9 nm, less than or equal to about 8 nm, less than or equal to about 7 nm, less than or equal to about 6 nm, or less than or equal to about 5 nm.

In an embodiment, the thickness of each of the electron auxiliary layers 40 (e.g., electron injection layer, electron transport layer, or hole blocking layer) may be greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, or greater than or equal to about 20 nm, and less than or equal to about 120 nm, less than or equal to about 110 nm, less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 30 nm, or less than or equal to about 25 nm, but is not limited thereto.

A device according to an embodiment may have a normal structure. In an embodiment, in the device, the first electrode 10 disposed on the transparent substrate 100 may include a metal oxide-based transparent electrode (e.g., an ITO electrode), and the second electrode (cathode) 50 facing the first electrode 10 may include a conductive metal (e.g., having a relatively low work function, Mg, Al, etc.). The hole auxiliary layer 20 (e.g., a hole injection layer such as PEDOT:PSS, p-type metal oxide, or a combination thereof; a hole transport layer such as TFB, polyvinylcarbazole (PVK), or a combination thereof; or a combination thereof) may be provided between the transparent electrode 10 and the light emitting layer 30. The hole injection layer may be disposed close to the transparent electrode and the hole transport layer may be disposed close to the light emitting layer. The electron auxiliary layer 40 such as an electron injection/transport layer may be disposed between the light emitting layer 30 and the second electrode 50. (Refer to FIG. 2)

A device according to an embodiment may have an inverted structure. The second electrode 50 disposed on the transparent substrate 100 may include a metal oxide-based transparent electrode (e.g., ITO), and the first electrode 10 facing the second electrode 50 may include a metal (e.g., having a relatively high work function, Au, Ag, etc.). For example, an (optionally doped) n-type metal oxide (crystalline Zn metal oxide) or the like may be disposed as an electron auxiliary layer 40 (e.g., an electron transport layer) between the transparent electrode 50 and the light emitting layer 30. a hole auxiliary layer 20 (e.g., a hole transport layer including TFB, PVK, or a combination thereof; a hole injection layer including MoO₃ or other p-type metal oxide; or a combination thereof) may be disposed between the metal first electrode 10 and the light emitting layer 30. (Refer to FIG. 3)

The aforementioned device may be produced by an appropriate method. For example, the electroluminescent device may be produced by optionally forming a hole auxiliary layer (e.g., by deposition or coating) on a substrate on which an electrode is formed, forming a light emitting layer including nanoparticles (e.g., a pattern of the aforementioned semiconductor nanoparticle), and forming (optionally, an electron auxiliary layer and) an electrode (e.g., by vapor deposition or coating) on the light emitting layer. A method of forming the electrode/hole auxiliary layer/electron auxiliary layer may be appropriately selected and is not particularly limited.

The electroluminescent device may be configured to emit blue light. The wavelength range of blue light is as described above.

The electroluminescent device may have a maximum external quantum efficiency of greater than or equal to about 4%, greater than or equal to about 5%, greater than or equal to about 6%, greater than or equal to about 7%, greater than or equal to about 8%, greater than or equal to about 9%, greater than or equal to about 10%, greater than or equal to about 10.5%, greater than or equal to about 11%, greater than or equal to about 11.5%, greater than or equal to about 12%, greater than or equal to about 12.5%, greater than or equal to about 13%, greater than or equal to about 13.5%, or greater than or equal to about 14%. The electroluminescent device may have a maximum external quantum efficiency of less than or equal to about 50%, less than or equal to about 40%, less than or equal to about 30%, or less than or equal to about 20%.

The electroluminescent device may have a maximum luminance of greater than or equal to about 40,000 nit (cd/m²), greater than or equal to about 50,000 nit, greater than or equal to about 60,000 nit, greater than or equal to about 70,000 nit, greater than or equal to about 80,000 nit, greater than or equal to about 90,000 nit, greater than or equal to about 95,000 nit, greater than or equal to about 100,000 nit, greater than or equal to about 105,000 nit, greater than or equal to about 110,000 nit, greater than or equal to about 115,000 nit, greater than or equal to about 120,000 nit, or greater than or equal to about 125,000 nit. The maximum luminance may be about 3,000 nit to about 500,000 nit.

The electroluminescent device can exhibit improved life-span. In an embodiment, the life-span of the electroluminescent device can be measured while driving at a predetermined initial luminance (e.g., about 146 nit or about 650 nit).

The life-span T50 of the electroluminescent device may be greater than or equal to about 10 hours, greater than or equal to about 50 hours, greater than or equal to about 80 hours, greater than or equal to about 100 hours, greater than or equal to about 150 hours, greater than or equal to about 300 hours, greater than or equal to about 310 hours, greater than or equal to about 350 hours, greater than or equal to about 380 hours, greater than or equal to about 400 hours, greater than or equal to about 450 hours, or greater than or equal to about 500 hours, and T90 may be greater than or equal to about 10 hours, greater than or equal to about 15 hours, greater than or equal to about 20 hours, greater than or equal to about 25 hours, greater than or equal to about 30 hours, greater than or equal to about 35 hours, greater than or equal to about 40 hours, greater than or equal to about 50 hours, greater than or equal to about 75 hours, greater than or equal to about 100 hours, greater than or equal to about 125 hours, greater than or equal to about 150 hours, greater than or equal to about 175 hours, or greater than or equal to about 200 hours.

In an embodiment, T50 may be about 150 hours to about 5,000 hours, about 400 hours to about 4,000 hours, about 500 hours to about 3,500 hours, about 750 hours to about 2,000 hours, about 1,000 hours to about 1,500 hours, or a combination thereof.

In an embodiment, the T90 may be about 13 hours to about 2,000 hours, about 15 hours to about 1,800 hours, about 18 hours to about 1,200 hours, about 22 hours to about 1,000 hours, about 31 hours to about 800 hours, about 50 hours to about 700 hours, about 60 hours to about 500 hours, about 80 hours to about 400 hours, or a combination thereof.

An embodiment relates to a display device (e.g., a display panel) including an electroluminescent device according to an embodiment.

The display device (e.g., a display panel) may include a first pixel and a second pixel configured to emit light of a different color from the first pixel. In an embodiment, the first light from the light emitting layer may be extracted (e.g., in the Z direction) through the second electrode (Refer to FIG. 4). In an embodiment, the first light may be extracted through the (transparent) first electrode and optionally the substrate 100 (Refer to FIG. 3). The light emitting layer may be arranged within a pixel (or subpixel) in a display device (display panel) described later.

FIG. 6 is a schematic cross-sectional view of a light emitting device (RGB pixel). The light emitting device includes a driving circuit and substrate, a transparent electrode 10, pixel defining layer PDL, a hole auxiliary layer 20, a red light emitting layer 30R, a green light emitting layer 30G, a blue light emitting layer 30B, an electron auxiliary layer 40, and a second electrode 50.

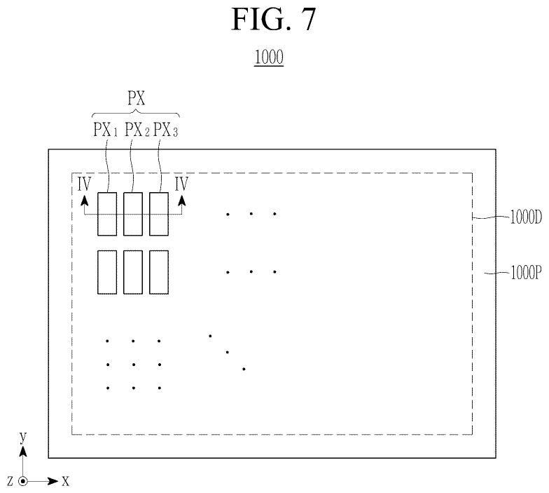

Referring to FIG. 7, a display panel 1000 according to an embodiment may include a display area 1000D for displaying an image and, optionally, a non-display area 1000P located around the display area 1000D and having a bonding material disposed thereon.

The display area 1000D may include a plurality of pixels PX arranged along rows (e.g., in the x direction), columns (e.g., in the y direction), or a combination thereof, and each pixel PX may include a plurality of subpixels PX₁, PX₂, and PX₃ that display different colors. As an example, a configuration in which three subpixels PX₁, PX₂, and PX₃ form one pixel is illustrated, but the present disclosure is not limited thereto and may further include additional subpixels such as a white subpixel, or may further include one or more subpixels displaying the same color. The plurality of subpixels PXs may be arranged in, for example, a Bayer matrix, a PenTile matrix, a diamond matrix, or a combination thereof, but is not limited thereto.

Each subpixel PX₁, PX₂, and PX₃ may display a color of three primary colors or a combination of three primary colors, for example, red, green, blue, or a combination thereof. For example, a first subpixel PX₁ may display red, a second subpixel PX₂ may display green, and a third subpixel PX₃ may display blue.

Although the drawing illustrates an example in which all subpixels have the same size, the present disclosure is not limited thereto, and a subpixel, e.g., at least one of the subpixels, may be larger or smaller than the other subpixels. Although the drawing illustrates an example in which all subpixels have the same shape, the present disclosure is not limited thereto, and a subpixel, e.g., at least one of the subpixels, may have a different shape from the other subpixels.

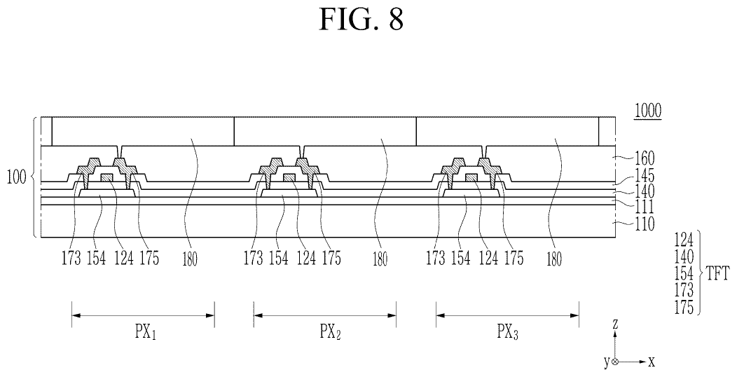

In an embodiment, the display panel may include a light emitting panel 100 including a substrate 110, a buffer layer 111, a thin film transistor (TFT), and a light emitting device 180. The display panel may include circuit elements for switching each light emitting device, driving each light emitting device, or a combination thereof. Referring to FIG. 8, in the light emitting panel, light emitting devices 180 may be arranged in each subpixel PX₁, PX₂, and PX₃, and the light emitting devices 180 arranged in the subpixels PX₁, PX₂, and PX₃ may be driven independently. The subpixel may include a blue subpixel, a red subpixel, or a green subpixel. A light emitting device 180, e.g., at least one of the light emitting devices 180, may be an electroluminescent device according to an embodiment.

The substrate 110 is as described above. The buffer layer 111 may include an organic, inorganic or organic-inorganic material, and may include, for example, an oxide, a nitride or an oxynitride, and may include, for example, silicon oxide, silicon nitride, silicon oxynitride or a combination thereof, but is not limited thereto. The buffer layer 111 may have one layer or two or more layers and may cover the entire surface of the lower substrate 110. The buffer layer 111 may be omitted.

The thin film transistor TFT may be a three-terminal device for switching a light emitting device 180, driving a light emitting device 180, or a combination thereof, and may include one or more for each subpixel. The thin film transistor TFT includes a gate electrode 124, a semiconductor layer 154 overlapped with the gate electrode 124, a gate insulating film 140 between the gate electrode 124 and the semiconductor layer 154, and a source electrode 173 and a drain electrode 175 electrically connected to the semiconductor layer 154. The drawing shows a coplanar top gate structure as an example, but is not limited thereto and may have various structures.

The gate electrode 124 is electrically connected to a gate line (not shown) and may include a low-resistance metal such as aluminum (Al), molybdenum (Mo), copper (Cu), titanium (Ti), silver (Ag), gold (Au), alloys thereof, or a combination thereof, but is not limited thereto.

The semiconductor layer 154 may be an inorganic semiconductor such as amorphous silicon, polycrystalline silicon, an oxide semiconductor; an organic semiconductor; an organic-inorganic semiconductor; or a combination thereof. For example, the semiconductor layer 154 may include an oxide semiconductor including indium (In), zinc (Zn), tin (Sn), gallium (Ga), or a combination thereof, and the oxide semiconductor may include, for example, indium-gallium-zinc oxide, zinc-tin oxide, or a combination thereof, but is not limited thereto. The semiconductor layer 154 may include a channel region and a doped region disposed on both sides of the channel region and electrically connected to the source electrode 173 and the drain electrode 175, respectively.

The gate insulating film 140 may include an organic, inorganic or organic-inorganic material, and may include, for example, an oxide, a nitride or an oxynitride, and may include, for example, silicon oxide, silicon nitride, silicon oxynitride, or a combination thereof, but is not limited thereto. The drawing shows an example in which the gate insulating film 140 is formed on the entire surface of the lower substrate 110, but is not limited thereto and may be selectively formed between the gate electrode 124 and the semiconductor 154. The gate insulating film 140 may have one layer or two or more layers.

The source electrode 173 and the drain electrode 175 may include a low-resistance metal such as aluminum (Al), molybdenum (Mo), copper (Cu), titanium (Ti), silver (Ag), gold (Au), alloys thereof, or a combination thereof, but is not limited thereto. The source electrode 173 and the drain electrode 175 may each be electrically connected to the doping region of the semiconductor layer 154. The source electrode 173 is electrically connected to a data line (not shown), and the drain electrode 175 is electrically connected to a light emitting device 180 described above.

An interlayer insulating film 145 is additionally formed between the gate electrode 124 and the source/drain electrodes 173 and 175. The interlayer insulating film 145 may include an organic, inorganic or organic-inorganic material, and may include, for example, an oxide, a nitride or an oxynitride, and may include, for example, silicon oxide, silicon nitride, silicon oxynitride, or a combination thereof, but is not limited thereto. The interlayer insulating film 145 may have one layer or two or more layers.

In an embodiment, a protective film 160 may be formed on a thin film transistor TFT. The protective film 160 may be, for example, a passivation film, but is not limited thereto. The protective film 160 may include an organic, inorganic or organic-inorganic material, and may include polyacrylic, polyimide, polyamide, polyamideimide or a combination thereof, but is not limited thereto. The protective film 160 may have one or more layers.

In an embodiment, one of the first electrodes 1 and 10 and the second electrodes 5 and 50 may be a pixel electrode connected to the TFT and the other may be a common electrode.

The electroluminescent device of an embodiment or the display device including the same may be used in a top emission manner, a bottom emission manner, a double-sided emission manner, or a combination thereof.

In an embodiment, the first electrode 10 may be a light transmitting electrode and the second electrode 50 may be a reflective electrode, and the display panel may be a bottom emission type display panel that emits light toward the first electrode 10 and, if present, the substrate 110. In an embodiment, the first electrode 10 may be a reflective electrode and the second electrode 50 may be a light transmitting electrode, and the display panel may be a top emission type display panel that emits light opposite the first electrode 10 and, if present, the substrate 100. In an embodiment, both the first electrode and the second electrode may be light transmitting electrodes, and the display panel 1000 may be a both side emission type display panel that emits light to the substrate 110 side and the opposite side of the substrate 110.

The display device may include a VR/AR device, a portable terminal device, a monitor, a laptop, a television, an electronic board, a camera, or an electrical component (for example, for an automobile).

Hereinafter, specific examples are illustrated. However, these examples are exemplary, and the present disclosure is not limited thereto.

### EXAMPLES

### Analysis Methods

1. Photoluminescence and UV-Vis absorption Analysis

(1) Photoluminescence spectra and absolute quantum yield (QY) of nanoparticles are obtained at room temperature using a Hitachi F-7000 spectrophotometer or a Hamamatsu QY instrument (Quantaurus-QY Absolute PL quantum yield spectrophotometer C11347-11) at an irradiation wavelength of 372 nanometers (nm).

(2) A UV spectroscopy analysis is performed using an Agilent Cary 5000 spectrophotometer to obtain a UV-Visible absorption spectrum.

### 2. Transmission Electron Microscope Analysis

Transmission electron microscopy images of the produced nanoparticles are obtained using a UT F30 Tecnai electron microscope.

### 3. Inductively Coupled Plasma (ICP) Analysis

Inductively coupled plasma atomic emission spectroscopy (ICP-AES) is performed using a Shimadzu ICPS-8100.

### 4. Electroluminescent Property Analysis and Life-Span Measurement

When applying voltage, the current according to the voltage is measured using a Keithley 2635B source meter, and the EL luminescence luminance is measured using a CS2000 spectrometer.

T90(h): when driving with predetermined luminance (e.g., 650 nit), time (hr) taken for the luminance to reach 90% based on 100% of the initial luminance is measured.

T50(h): when driving with predetermined luminance (e.g., 650 nit), time (hr) taken for the luminance to reach 50% based on 100% of the initial luminance is measured.

The following synthesis is performed under an inert gas atmosphere (under a nitrogen flowing condition), unless otherwise specified. A precursor amount is a molar content, unless otherwise specified.

### Reference Example: Synthesis of ZnMgO Nanoparticles

Zinc acetate dihydrate and magnesium acetate tetrahydrate are added to a reactor containing dimethylsulfoxide and heated at 60° C. in air. Subsequently, an ethanol solution of tetramethylammonium hydroxide pentahydrate is added to the reactor. After stirring the mixture for 1 hour, a precipitate form and is separated from the reaction mixture with a centrifuge. The precipitate is dispersed in ethanol to obtain Zn₁₋ₓMgₓO nanoparticles. (x=0.15) The obtained nanoparticles are subjected to a transmission electron microscope analysis. The particles have an average size of about 3 nm.

### Preparation Example 1

1. Selenium (Se), sulfur(S), and tellurium (Te) are dispersed in trioctylphosphine (TOP) to obtain 2 M Se/TOP stock solution, 1 M S/TOP stock solution, and 0.1 molar (M) Te/TOP stock solution.

Oleic acid and oleylamine are placed in a reaction flask including trioctylamine and heated at 120° C. under vacuum, and after 15 minutes, the atmosphere inside the reactor is changed to nitrogen.

The reaction flask is heated to 240° C., 9 millimoles (mmol) of diethylzinc is injected, and then a mixture of Se/TOP stock solution (first selenium precursor) (3.5 mmol), Te/TOP stock solution (0.225 mmol), and DPP (4.5 mmol) is immediately added, and the first reaction is performed for 10 minutes. Then, a second selenium precursor (1.0 mmol) is added. After 30 minutes, the reaction flask is quickly cooled to room temperature, ethanol is added to the reaction flask, and ZnSeTe first semiconductor nanocrystals are obtained by centrifugation. The first semiconductor nanocrystal is dispersed in hexane to obtain a first semiconductor nanocrystal solution.

The total amount of the second selenium precursor and the first selenium precursor per 1 mole of the Te precursor was 20 moles, and the molar ratio between the first selenium precursor and the second selenium precursor is 7:2.

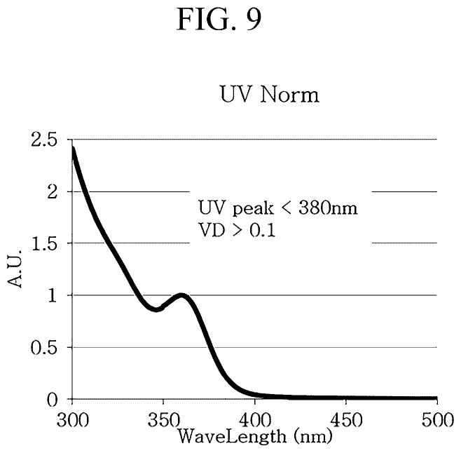

After the first reaction, a sample is collected from the reaction solution and subjected to UV-Vis absorption spectroscopy, and the results are shown in FIG. 9. From the results of FIG. 9, the ZnTeSe nucleus in the reaction solution has a valley depth (VD) of 0.1 or higher in the UV-Vis absorption spectrum.

ICP analysis and photoluminescent spectroscopy analysis are performed on the produced first semiconductor nanocrystal and the results are summarized in Table 4.

2. Zinc acetate (4.8 mmol) and oleic acid (9.6 mmol) are added to a reaction flask including 80 milliliters (mL) trioctylamine (TOA) and vacuum treated at 120° C. The interior of the flask is replaced with nitrogen (N₂), the reaction flask is heated to 280° C., and then cooled to 240° C. The first semiconductor nanocrystal solution is quickly added to the reaction flask, and then HF aqueous solution diluted with acetone (10 weight percent (wt %), 0.44 mL) and ZnCl₂ (0.09 mmol) were injected, and the flask is heated to 340° C. Then, zinc precursor (ZnOA₂, 12 mmol) and Se/TOP stock solution (8 mmol) are added and the reaction is performed for 30 minutes. Subsequently, S/TOP stock solution (11.2 mmol) is added together with additional zinc precursor (16.8 mmol) and the reaction was continued for 90 minutes.

The amount of selenium precursor used per 1 mole of zinc precursor is 0.48 moles, and with respect to the formation of the ZnS shell, the amount of sulfur precursor used per 1 mole of zinc precursor is 0.67 moles.

After the reaction is completed, the reactor is cooled to room temperature and ethanol is added to the reaction solution to precipitate the produced nanoparticles. The precipitate is recovered by centrifugation, and the obtained nanoparticles are dispersed in octane.

### 3. ICP Analysis is Performed on the Produced Semiconductor Nanoparticle, and the Results are Summarized in Table 1.

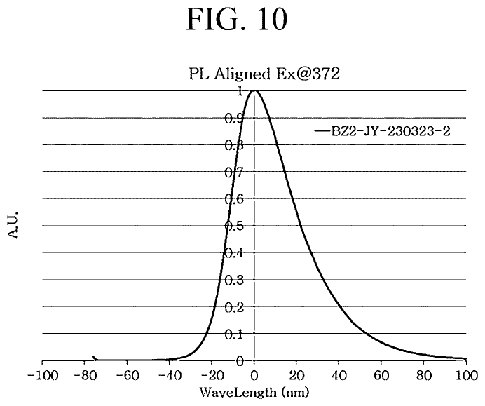

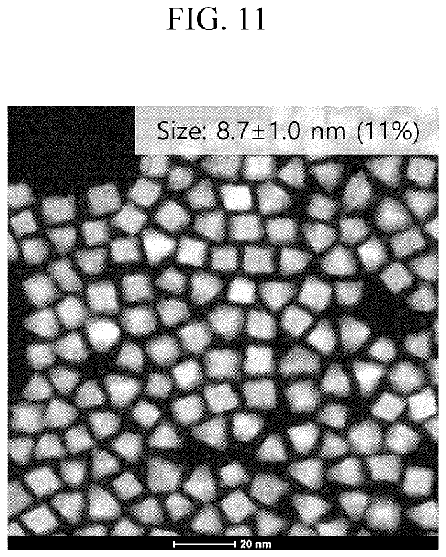

Photoluminescence analysis is performed on the produced semiconductor nanoparticle, and the results are shown in FIG. 10. The photoluminescent peak wavelength of the semiconductor nanoparticle of Example 1 is 457 nm and the full width at half maximum is 38 nm. In FIG. 10, the x-axis indicates the peak emission wavelength as 0 nm, 50 nm is the trap emission wavelength, and the y-axis is normalized based on the intensity at the maximum emission peak wavelength. Transmission electron microscopy (TEM) analysis is performed on the produced semiconductor nanoparticle and the results are shown in FIG. 11.

### Comparative Preparation Example 1

1. A first semiconductor nanocrystal is produced in the same manner as Preparation Example 1, except that 4.5 mmol of the first selenium precursor is used without using the second selenium precursor. ICP analysis and photoluminescent spectroscopy analysis are performed on the produced first semiconductor nanocrystal and the results are summarized in Table 4.

2. A semiconductor nanoparticle is obtained in the same manner as in Preparation Example 1, except that the first semiconductor nanocrystal obtained above is used.

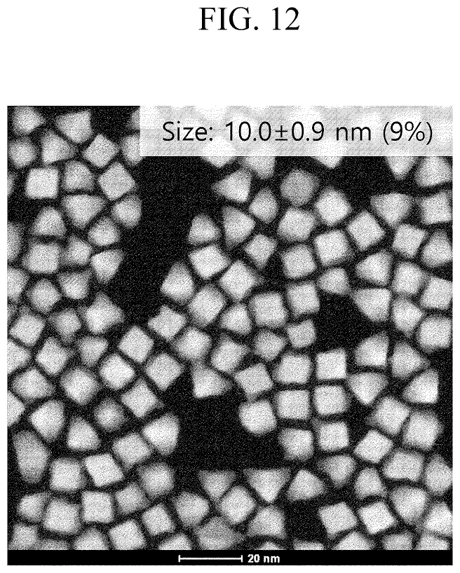

3. ICP analysis is performed on the produced semiconductor nanoparticle, and the results are summarized in Table 1. TEM analysis is performed on the produced semiconductor nanoparticle, and the results are shown in Table 2 and FIG. 12. Photoluminescence analysis was performed on the produced semiconductor nanoparticle, and the results are summarized in Table 2. The photoluminescent peak wavelength of the semiconductor nanoparticle of Comparative Preparation Example 1 is 459 nm and the full width at half maximum is approximately 40 nm.

### Preparation Example 2

1. Selenium (Se), sulfur(S), and tellurium (Te) are dispersed in trioctylphosphine (TOP) to obtain 2 M Se/TOP stock solution, 1 M S/TOP stock solution, and 0.1 M Te/TOP stock solution. Zinc acetate is placed together with oleic acid in a 300 mL reaction flask containing TOA and treated under vacuum at 120° C. to obtain zinc oleate.

Oleic acid (13.5 mmol) and oleylamine (9 mmol) are added to a reaction flask including 50 mL of trioctylamine and heated at 120° C. under vacuum, and after 15 minutes, the atmosphere inside the reactor is changed to nitrogen. The reaction flask is heated to 240° C., 9 mmol of diethylzinc is injected, and then a mixture of Se/TOP stock solution (first selenium precursor) (3.5 mmol), Te/TOP stock solution (0.225 mmol), and DPP (4.5 mmol) is immediately added, and the first reaction is performed for 10 minutes. Then, a second selenium precursor (1.0 mmol) is added and the reaction is continued for an additional 20 minutes.

Then, zinc compound (zinc oleate) (3.75 mmol) and second selenium precursor (2.5 mmol) are added, and the reaction flask is heated to 340° C. After 10 minutes, the reaction flask is quickly cooled to room temperature, ethanol is added to the reaction flask, and ZnSeTe first semiconductor nanocrystals are obtained by centrifugation. The first semiconductor nanocrystal is dispersed in hexane to obtain a first semiconductor nanocrystal solution. ICP analysis and photoluminescent spectroscopy analysis are performed on the produced first semiconductor nanocrystal and the results are summarized in Table 4.

2. A semiconductor nanoparticle is obtained in the same manner as in Preparation Example 1, except that the first semiconductor nanocrystal obtained above is used and the shell formation conditions (precursor content) are partially adjusted to obtain the composition set forth in Table 1.

3. ICP analysis is performed on the produced semiconductor nanoparticle, and the results are summarized in Table 1.

### Preparation Example 3

1. The first semiconductor nanocrystal is prepared in the same manner as in Preparation Example 2, except that zinc oleate and zinc chloride are added as the zinc compound. ICP analysis and photoluminescent spectroscopy analysis are performed on the produced first semiconductor nanocrystal and the results are summarized in Table 4.

2. A semiconductor nanoparticle is obtained in the same manner as in Preparation Example 2, except that the first semiconductor nanocrystal obtained above is used.

3. ICP analysis is performed on the produced semiconductor nanoparticle, and the results are summarized in Table 1.

TABLE 1

| | Te:Se | Se:(S + Se) | (S + Se):Zn | S:Se | Te:S | Se:Zn |
|---|---|---|---|---|---|---|
| Comparative | 0.0035:1 | 0.6280:1 | 0.8447:1 | 0.5923:1 | 0.0059:1 | 0.5305:1 |
| Preparation | | | | | | |
| Example 1 | | | | | | |
| Preparation | 0.0070:1 | 0.6313:1 | 0.8312:1 | 0.5839:1 | 0.0120:1 | 0.5248:1 |
| Example 1 | | | | | | |
| Preparation | 0.0072:1 | 0.6048:1 | 0.8466:1 | 0.6534:1 | 0.0110:1 | 0.5120:1 |
| Example 2 | | | | | | |
| Preparation | 0.0034:1 | 0.6216:1 | 0.8992:1 | 0.6088:1 | 0.0056:1 | 0.5589:1 |
| Example 3 | | | | | | |

TABLE 2

| | | Intensity at | |
|---|---|---|---|
| | | PWL + 50 nm | Average |
| | | relative to | particle |
| | PLQY | intensity at PWL | size |
| Preparation | 97% | 0.12 | 8.7 nm |
| Example 1 | | | |
| Comparative | about 90% | 0.15 | 10 nm |
| Preparation | | | |
| Example 1 | | | |

PLQY: Absolute quantum efficiency (photoluminescent quantum yield)
PWL: emission peak wavelength

TABLE 4

| | | | PWL |
|---|---|---|---|
| | Te:Se | Zn:(Te + Se) | (nm) |
| Comp. preparation Example 1 | 0.053:1 | 1.309:1 | 415 |
| Preparation Example 1 | 0.052:1 | 1.252:1 | 421 |
| Preparation Example 2 | 0.031:1 | 1.16:1 | 445 |
| Preparation Example 3 | 0.025:1 | 1.23:1 | 438 |

PWL: peak emission wavelength

From Table 4, it can be seen that in the case of the first semiconductor nanocrystal formed in the preparation example, the Te:Se molar ratio is smaller than that of the comparative example, but the peak emission wavelength is longer than that of the comparative example.

### Example 1

Using the semiconductor nanoparticle produced in Preparation Example 1, a light emitting device having the structure of indium tin oxide (ITO)/poly(3,4-ethylenedioxythiophene) polystyrene sulfonate (PEDOT:PSS) (300 angstroms)/poly(9,9-dioctyl-fluorene-co-N-(4)-butylphenyl)-diphenylamine) (TFB) (250 angstroms)/semiconductor nanoparticle emitting layer (360 angstroms)/ZnMgO (240 angstroms)/Al is manufactured using the following method, and the electroluminescent properties are measured:

PEDOT:PSS and TFB layers are formed as a hole injection layer and a hole transport layer by spin coating on a glass substrate on which an ITO electrode (first electrode) is deposited. A light emitting layer was formed by spin-coating the semiconductor nanoparticle solution prepared in Preparation Example 1 on the formed TFB layer (25 nm). A zinc magnesium oxide nanoparticle layer is formed as the electron auxiliary layer on the light emitting layer, and then an Al electrode is formed by deposition to manufacture a light emitting device.

The electroluminescent property and life-span of the manufactured devices are measured. It was confirmed that the EQE and the T90 of the device was greater than or equal to 13% and 18 hours. The electroluminescent properties are summarized in Table 2.

### Comparative Example 1

An electroluminescent device is manufactured in the same manner as in Example 1, except that the semiconductor nanoparticle produced in Comparative Preparation Example 1 are used.

The electroluminescent property and life-span of the manufactured devices are measured. The electroluminescent properties are summarized in Table 3.

TABLE 3

| | Relative | Relative | EL | | |
|---|---|---|---|---|---|
| | Max. | Max. | Max. at | Relative | Relative |
| | EQE | luminance | 650 nit | T90 | T50 |
| Comparative | 100% | 100% | 463 nm | 100% | 100% |
| Example 1 | | | | | |
| Example 1 | 116% | 105% | 462 nm | 506% | 158% |

Relative Max. EQE: Maximum external quantum efficiency of a given device/Maximum external quantum efficiency of the device in Comparative Example 1
Relative Max. luminance: Maximum luminance of a given device/Maximum luminance of the device in Comparative Example 1
EL Max. at 650 nit: electroluminescent peak wavelength at 650 nit
Relative T90: T90 (hour) of the given device/T90 (hour) of the device of Comparative Example 1
Relative T50: T50 (hour) of the given device/T50 (hour) of the device of Comparative Example 1

From the results in Table 3, the device of Example 1 can exhibit improved electroluminescent property and increased life-span compared to the device of Comparative Example 1.

While this disclosure has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A method for producing a semiconductor nanoparticle, comprising
preparing a first semiconductor nanocrystal comprising zinc, tellurium, and selenium,
wherein the preparing of the first semiconductor nanocrystal comprises
heating a first solution comprising a first zinc precursor, a first selenium precursor, and a tellurium precursor in a first organic solvent at a reaction temperature to form a heated first solution; and
adding an additive to the heated first solution,
wherein the additive comprises a second selenium precursor and the additive does not comprise tellurium, and
the semiconductor nanoparticle is configured to emit blue light.

2. The method of claim 1, wherein
the method further comprises heating a second zinc precursor and a chalcogen precursor in a second organic solvent in the presence of the first semiconductor nanocrystal and an organic ligand to obtain semiconductor nanoparticle.

3. The method of claim 1, wherein
the additive further comprises a zinc compound, hydrofluoric acid, or a combination thereof.

4. The method of claim 1, wherein
an amount of the second selenium precursor is about 0.1 to about 10 moles per 1 mole of the first selenium precursor.

5. The method of claim 1, wherein
the additive comprises the second selenium precursor and a zinc compound,
the first selenium precursor is the same as or different from the second selenium precursor,
the first zinc precursor is different from the zinc compound, and
the zinc compound comprises a zinc carboxylate, a zinc halide, or a combination thereof.

6. The method of claim 5, wherein
the first zinc precursor comprises a dialkylzinc, and
the zinc compound comprises a zinc carboxylate and optionally zinc chloride.

7. The method of claim 1, wherein
a total amount of the first selenium precursor and the second selenium precursor is greater than or equal to about 10 moles and less than or equal to about 55 moles per 1 mole of the tellurium precursor, and
a molar ratio between the first selenium precursor and the second selenium precursor is about 1:0.1 to about 1:0.5.

8. The method of claim 1, wherein
in the semiconductor nanoparticle,
a molar ratio of tellurium to selenium is greater than or equal to about 0.0005:1 and less than or equal to about 0.008:1.

9. The method of claim 1, wherein
in the semiconductor nanoparticle,
a molar ratio of selenium to a total sum of sulfur and selenium is about 0.55:1 to about 0.65:1, or
a molar ratio of tellurium to sulfur is about 0.005:1 to about 0.05:1, or
a molar ratio of selenium to zinc is about 0.5:1 to about 0.6:1.

10. The method of claim 1, wherein
the semiconductor nanoparticle is configured to emit a first light when voltage is applied, and an electroluminescent peak wavelength of the first light is greater than about 460 nanometers and less than or equal to about 490 nanometers.

11. Semiconductor nanoparticles, comprising
zinc, tellurium, selenium, and sulfur,
wherein the semiconductor nanoparticles do not comprise cadmium,
in the semiconductor nanoparticles, a molar ratio of tellurium to selenium is greater than or equal to about 0.0005:1 and less than or equal to about 0.008:1,
the semiconductor nanoparticles have an average particle size of less than about 10.3 nanometers, and
the semiconductor nanoparticles have an absolute quantum efficiency of greater than or equal to about 90%.

12. The semiconductor nanoparticles of claim 11, wherein
the semiconductor nanoparticles have an average particle size of less than about 10 nanometers and an absolute quantum efficiency of greater than or equal to about 93%.

13. The semiconductor nanoparticles of claim 11, wherein
in an emission spectrum the semiconductor nanoparticles exhibit a ratio of an intensity at a peak emission wavelength+50 nanometers to an intensity at the peak emission wavelength that is less than or equal to about 0.12:1.

14. An electroluminescent device, comprising
a first electrode and a second electrode spaced apart from each other, and a light emitting layer disposed between the first electrode and the second electrode, the light emitting layer comprising a semiconductor nanoparticle,
wherein the semiconductor nanoparticle comprises zinc, tellurium, selenium, and sulfur,
the semiconductor nanoparticle does not comprise cadmium,
in the semiconductor nanoparticle, a molar ratio of tellurium to selenium is greater than or equal to about 0.0005:1 and less than or equal to about 0.008:1, and
the light emitting layer is configured to emit a first light by voltage application, and an electroluminescent peak wavelength of the first light or the semiconductor nanoparticle is greater than or equal to about 461 nanometers and less than or equal to about 490 nanometers.

15. The electroluminescent device of claim 14, wherein
the semiconductor nanoparticle has a ratio of an intensity at a peak emission wavelength+50 nanometers to an intensity at the peak emission wavelength in the emission spectrum of less than or equal to about 0.25:1.

16. The electroluminescent device of claim 14, wherein
a molar ratio of tellurium to selenium in the semiconductor nanoparticle is less than or equal to about 0.007:1, and the peak emission wavelength of the first light is less than or equal to about 462 nanometers.

17. The electroluminescent device of claim 14, wherein
the electroluminescent device has a maximum external quantum efficiency of greater than or equal to about 7% and a T90 of greater than or equal to about 15 hours when started at 650 nit.

18. The electroluminescent device of claim 14, wherein
in the semiconductor nanoparticle,
a molar ratio of selenium to the total sum of sulfur and selenium is about 0.55:1 to about 0.65:1, or
a molar ratio of tellurium to sulfur is about 0.005:1 to about 0.05:1, or
a molar ratio of selenium to zinc is about 0.5:1 to about 0.6:1.

19. A display device comprising the electroluminescent device of claim 14.

20. The display device of claim 19, wherein
the display device comprises a virtual reality device, an augmented reality device, a portable terminal, a monitor, a laptop, a television, an electronic board, a camera, or an electrical component.
